(19) United States
(12) Patent Application Publication
(10) Pub. No.: US 2026/0047463 A1
(43) Pub. Date: Feb. 12, 2026

(54) BONDED DIE STRUCTURES WITH IMPROVED BONDING AND METHODS OF FORMING THE SAME

(71) Applicant: Taiwan Semiconductor Manufacturing Company Limited, Hsinchu (TW)

(72) Inventors: Tzu Jung Tien, Hsinchu (TW); Jen-Yuan CHANG, Hsinchu City (TW)

(21) Appl. No.: 18/800,451

(22) Filed: Aug. 12, 2024

(51) Int. Cl. H01L 23/13; H01L 21/304; H01L 23/00; H01L 23/14; H01L 23/48; H01L 25/065

(52) U.S. Cl. CPC H01L 23/13; H01L 21/3043; H01L 23/14; H01L 24/05; H01L 24/08; H01L 24/80; H01L 23/481; H01L 24/02; H01L 24/96; H01L 24/97; H01L 25/0657; H01L 2224/0235; H01L 2224/02372; H01L 2224/02381; H01L 2224/05009; H01L 2224/05624; H01L 2224/05647; H01L 2224/05684; H01L 2224/08145; H01L 2224/80895; H01L 2224/80896; H01L 2224/96; H01L 2224/97; H01L 2924/1815

(57) ABSTRACT

Bonded die structures and methods of fabrication thereof that provide reduced defects and higher reliability. A laser grooving process may be used to “precut” bonded device structures prior to a final dicing process. The laser grooving process may form relatively deep grooves in the bonded device structure that may extend beyond the bonding interface between a first device structure and a second device structure. A final dicing process along the precut grooves may be used to separate individual bonded die structures. Because the dicing occurs along the deep precut grooves that extend through the bonding interface between the stacked device structures, the dicing blade may not cut through or come into contact with the bonding interface. This may result in in reduced mechanical stress, which may decrease the occurrence of delamination defects between the device structures and thereby provide improved reliability and increased yields.

### BACKGROUND

The semiconductor industry has grown due to continuous improvements in integration density of various electronic components (e.g., transistors, diodes, resistors, capacitors, etc.).

In addition to smaller electronic components, improvements to the packaging of components have been developed in an effort to provide smaller packages that occupy less area than previous packages. Example approaches include quad flat pack (QFP), pin grid array (PGA), ball grid array (BGA), flip chips (FC), three-dimensional integrated circuits (3DICs), wafer level packages (WLPs), package on package (PoP), System on Chip (SoC) or System on Integrated Circuit (SoIC) devices. Some of these three-dimensional devices are prepared by placing chips over chips. These three-dimensional devices provide improved integration density and other advantages because of the decreased length of interconnects between the stacked chips. However, there are many challenges related to three-dimensional devices.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view illustrating a portion of a first device structure according to various embodiments of the present disclosure.

FIG. 2 is a vertical cross-sectional view illustrating a portion of a second device structure according to various embodiments of the present disclosure.

FIG. 3 is a vertical cross-section view illustrating the second device structure bonded to the first device structure to form a bonded device structure according to various embodiments of the present disclosure.

FIG. 4 is a vertical cross-section view of bonded device structure including a plurality of grooves formed in the bonded device structure according to various embodiments of the present disclosure.

FIG. 5 is a vertical cross-section view of a bonded die structure according to various embodiments of the present disclosure.

FIG. 6 is a vertical cross-section view of a bonded die structure including a plurality of solder balls over the front side of the bonded die structure according to various embodiments of the present disclosure.

FIG. 7 is a vertical cross-section view showing the bonded die structure on a support structure according to various embodiments of the present disclosure.

FIG. 8 is a vertical cross-section view of a bonded device structure illustrating a plurality of first grooves formed in the bonded device structure according to another embodiment of the present disclosure.

FIG. 9 is a vertical cross-section view of a bonded device structure including second grooves formed in the bonded device structure according to another embodiment of the present disclosure.

FIG. 10 is a vertical cross-section view of a bonded die structure according to another embodiment of the present disclosure.

FIG. 11 is a vertical cross-section view of a bonded device structure including first grooves formed in the bonded device structure according to another embodiment of the present disclosure.

FIG. 12 is a vertical cross-section view of a bonded device structure including second grooves formed in the bonded device structure according to another embodiment of the present disclosure.

FIG. 13 is a vertical cross-section view of a bonded die structure according to another embodiment of the present disclosure.

FIG. 14 is a vertical cross-section view of a bonded device structure including first grooves formed in the bonded device structure according to another embodiment of the present disclosure.

FIG. 15 is a vertical cross-section view of a bonded device structure including second grooves formed in the bonded device structure according to another embodiment of the present disclosure.

FIG. 16 is a vertical cross-section view of a bonded die structure according to another embodiment of the present disclosure.

FIG. 17 is a vertical cross-section view illustrating a bonded device structure according to another embodiment of the present disclosure.

FIG. 18 is a vertical cross-section view of bonded device structure including a plurality of grooves formed in the bonded device structure according to various embodiments of the present disclosure.

FIG. 19 is a vertical cross-section view of a bonded die structure according to another embodiment of the present disclosure.

FIG. 20 is a vertical cross-section view of bonded device structure including a plurality of grooves formed in the bonded device structure according to another embodiment of the present disclosure.

FIG. 21 is a vertical cross-section view of a bonded die structure according to another embodiment of the present disclosure.

FIG. 22 is a vertical cross-section view illustrating a bonded device structure including a bonded die structure disposed on a carrier structure and laterally surrounded by a gap fill dielectric material according to an embodiment of the present disclosure.

FIG. 23 is a vertical cross-section view of a bonded device structure including a plurality of grooves formed in the gap fill dielectric material according to various embodiments of the present disclosure.

FIG. 24 is a vertical cross-section view of a bonded die structure according to another embodiment of the present disclosure

FIG. 25 is a flowchart illustrating a method of fabricating a bonded die structure according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein are directed to semiconductor devices, and specifically to bonded die structures that include a plurality of semiconductor integrated circuit (IC) dies bonded to one another. The bonded semiconductor IC dies may be in a configuration such as a system on integrated chip (SoIC), chip on wafer on substrate (CoWoS®), chip on wafer (CoW), etc. Such bonded die structures may increase the density of devices that may occupy a given planar area or “footprint.”

Semiconductor integrated circuits may include a semiconductor material substrate, such as a silicon substrate, having a number of circuit components and elements formed on and/or within the semiconductor material. Semiconductor integrated circuits are typically fabricated by sequentially depositing insulating or dielectric layers, conductive layers, and semiconductive layers of material over the semiconductor substrate (e.g., a wafer), and patterning the various material layers using lithography to form integrated circuits.

A bonded device structure may be formed by placing a second device structure (e.g., a semiconductor substrate or die, optionally having integrated circuits formed thereon) onto first device structure (e.g., a separate semiconductor substrate or die, optionally having integrated circuits formed thereon). A bonding process may be used to bond bonding features on the first device structure to corresponding bonding features on the second device structure. In some embodiments, a direct bonding technique, such as metal-to-metal (M-M) and dielectric-to-dielectric (D-D) bonding techniques, may be used to bond the device structures to form the bonded device structure. In such bonding techniques, bonding layers including an array of metal bonding pads surrounded by a dielectric material may be formed on the structures to be bonded. The bonding layer on the second device structure may be aligned over the corresponding bonding layer on the first device structure, and the two bonding layers may be brought into contact with one another. This may result in a chemical pre-bond between the dielectric material of the respective bonding layers. An annealing process may then be performed to promote bonding of the metal bonding pads of the respective bonding layers, thereby producing metal bonds extending between the first device structure and the second device structure. Other types of bonding processes, such as a fusion bonding process between dielectric bonding material layers, may also be utilized.

In some embodiments, a dicing process may be used to separate portions of the bonded device structure to form individual bonded die structures, where each bonded die structure may include a stack of two or more semiconductor IC dies that are bonded together. The dicing process typically utilizes a metal blade (e.g., a dicing saw) to mechanically saw through the various layers of the bonded device structure to separate individual bonded die structures. However, it has been found that the dicing process may result in an accumulation of mechanical stress at the bonding interface between the bonded device structures. This may cause delamination defects between the respective device structures which can lead to poor device reliability and reduced device yields for the bonded die structures.

Various embodiments disclosed herein are directed to bonded die structures and methods of fabrication thereof that may provide reduced defects and higher reliability. In various embodiments, a laser grooving process may be used to “precut” bonded device structures prior to a final dicing process. The laser grooving process may form relatively deep grooves in the bonded device structure that may extend beyond the bonding interface between a first device structure and a second device structure. A final dicing process along the precut grooves may then be utilized to separate individual bonded die structures. Because the dicing occurs along the deep precut grooves that extend through the bonding interface between the first device structure and a second device structure, the dicing blade may not cut through or come into contact with the bonding interface. This may result in in reduced mechanical stress, which may decrease the occurrence of delamination defects between the device structures and thereby provide improved reliability and increased yields.

Bonded die structure fabricated using an above-described laser grooving process may include a first die bonded to a second die at a bonding interface, and a sidewall having a non-planar contoured surface, where the plane containing the bonding interface between the first die and the second die may intersect the sidewall of the bonded die structure. In some embodiments, the bonding interface may be exposed along the sidewall having a non-planar contoured surface.

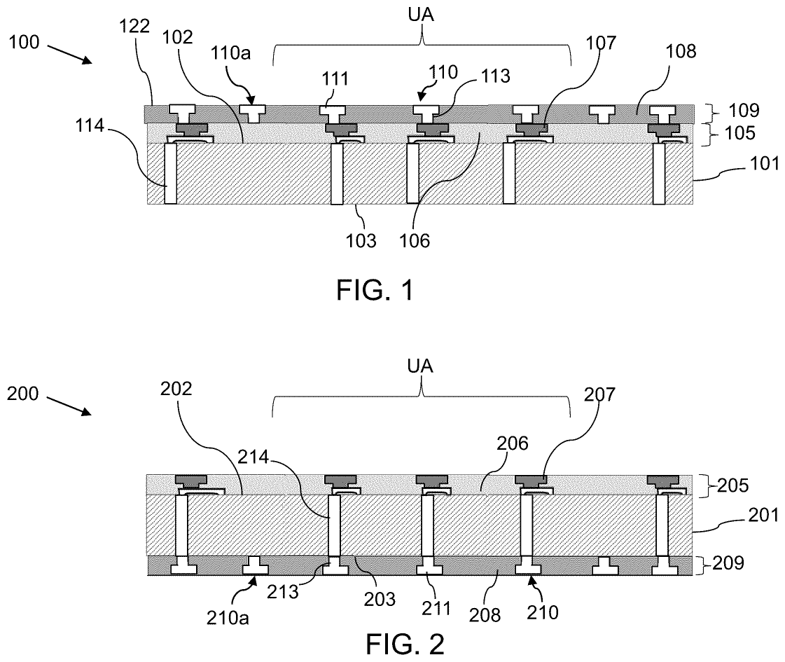

FIGS. 1-7 are sequential vertical cross-sectional views illustrating the intermediate structures during a process of fabricating a bonded die structure according to various embodiments of the present disclosure. FIG. 1 is a vertical cross-sectional view illustrating a portion of a first device structure 100 according to various embodiments of the present disclosure. The first device structure 100 may include a first semiconductor substrate 101 (e.g., a semiconductor wafer) that may include an elementary semiconductor such as silicon or germanium and/or a compound semiconductor such as silicon germanium, silicon carbide, gallium arsenic, indium arsenide, gallium nitride, or indium phosphide, or combinations of the same. Other semiconductor substrate materials are within the contemplated scope of disclosure. In some embodiments, the first semiconductor substrate 101 may be a semiconductor-on-insulator (SOI) substrate.

The first semiconductor substrate 101 may include a first major surface (i.e., a front side surface 102) and a second major surface (i.e., a backside surface 103). In some embodiments, a thickness of the first semiconductor substrate 101 between the front side surface 102 and the backside surface 103 may be between about 100 μm and about 800 μm, although a first semiconductor substrate 101 having a greater or lesser thickness may also be utilized.

In some embodiments, a plurality of devices (not shown in FIG. 1) may be disposed on, over and/or in the front side surface 102 of the first semiconductor substrate 101. The devices may include, for example, active devices, passive devices, or a combination thereof. In some embodiments, the devices disposed on, over and/or in the front side surface 102 of the first semiconductor substrate 101 may include integrated circuit devices. The integrated circuit devices may include, for example, transistors (e.g., field-effect transistors (FETs)), capacitors, resistors, diodes, photodiodes, fuse devices, or other similar devices. In some embodiments, the integrated circuit devices may include gate electrodes, source/drain regions, spacers, isolation trenches, and the like.

The first device structure 100 may additionally include a first interconnect structure 105 over the front side surface 102 of the first semiconductor substrate 101. The first interconnect structure 105 may include metal features 107 (e.g., metal lines, vias, etc.) formed within a dielectric material 106 (e.g., one or more inter-layer dielectric (ILD) layers and/or inter-metal dielectric (IMD) layers) that may provide connections to and/or between various devices located on, over and/or in the front side surface 102 of the first semiconductor substrate 101.

In some embodiments, the first device structure 100 may include one or more first through-substrate vias (TSVs) 114 extending through the first semiconductor substrate 101. The first TSVs 114 may provide electrical connections between devices and/or interconnect structures on the front side surface 102 of the first semiconductor substrate 101 and the backside surface 103 of the first semiconductor substrate 101.

The first device structure 100 may further include a first bonding layer 109 over the first interconnect structure 105 according to various embodiments of the present disclosure. The first bonding layer 109 may include one or more dielectric material layers 108 composed of suitable dielectric material(s), such as silicon oxide, silicon nitride, silicon carbide, silicon carbon nitride, silicon oxynitride, a dielectric polymer material, or the like. Other suitable dielectric materials are within the contemplated scope of disclosure. In various embodiments, the one or more dielectric material layers 108 may be deposited using any suitable deposition process. Herein, “suitable deposition processes” may include a chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like, including various combinations thereof. The first bonding layer 109 may have a planar upper surface 122, as shown in FIG. 1.

Referring again to FIG. 1, the first bonding layer 109 may also include a plurality of first metal bonding features 110, 110a. The first metal bonding features 110, 110a may bonding pads 111 and bonding vias 113. The bonding pads 111 and the bonding vias 113 of the first metal bonding features 110, 110a may be formed by forming a plurality of openings in the one or more dielectric material layers 108 of the first bonding layer 109 and depositing a metal material within the openings, such as via a damascene or dual-damascene process. This may include, for example, performing one or more etching processes through a lithographically-patterned mask to form openings in the one or more dielectric material layers 108, and depositing a suitable metal material within the openings to form the bonding pads 111 and/or the bonding vias 113. An optional planarization process may be used to remove excess conductive material from over the planar upper surface 122 of the first bonding layer 109. The bonding pads 111 and the bonding vias 113 of the first metal bonding features 110, 110a may include a suitable conductive material, such as copper (Cu), tungsten (W), aluminum (Al), and the like. The bonding pads 111 and the bonding vias 113 of the first metal bonding features 110, 110a may be formed using a suitable deposition process, such as, for example, physical vapor deposition (PVD), sputtering, chemical vapor deposition (CVD), atomic layer deposition (ALD), plasma-enhanced chemical vapor deposition (PECVD), electrochemical deposition (e.g., electroplating), or combinations thereof.

The first metal bonding features 110, 110a may be laterally surrounded by the dielectric material layer(s) 108 of the first bonding layer 109. At least some of the bonding pads 111 of the first metal bonding features 110, 110a may be electrically coupled to underlying metal features 107 of the first interconnect structure 105 via a bonding via 113.

FIG. 1 illustrates a unit area (UA) of the first device structure 100. The UA of the first device structure 100 may be a portion of the first device structure 100 that may be subsequently separated (i.e., singulated) from the remainder of the first device structure 100 to provide an integrated circuit (IC) die, as described further below. The UA may include a set of integrated circuit devices disposed on, over and/or in the front side surface 102 of the first semiconductor substrate 101, an interconnect structure 105 over the front side surface 102 of the first semiconductor substrate 101, and a portion of the first bonding layer 109. In some embodiments, the UA may lack devices disposed on, over and/or in the front side surface 102 of the first semiconductor substrate 101 and may instead be used to form non-functional or “dummy” dies within a multi-die bonded device structure. Non-functional “dummy” dies may be used, for example, for in-line process structure uniformity and/or for routing of electrical signals. A first device structure 100 may typically include a plurality of UAs that may each be separated from the first device structure 100 to form respective dies.

In some embodiments, at least a portion of the first metal bonding features 110a of the first bonding layer 109 may be located outside of the UA(s) of the first device structure 100, such as around the periphery of the UA(s) and/or between adjacent UAs of the first device structure 100 (e.g., within the scribe lanes of the first device structure 100). Thus, these bonding features 110a may not be present in any of the individual IC die(s) that are produced via the dicing process. However, as discussed in further detail below, the first metal bonding features 110a may aid in the subsequent dicing process by preferentially absorbing laser radiation during a laser grooving process that may be utilized to “precut” the individual UAs prior to performing the final dicing process. The first metal bonding features 110a located outside of the UA(s) of the first device structure 100 may be referred to as “dummy” first metal bonding features 110a.

FIG. 2 is a vertical cross-sectional view illustrating a portion of a second device structure 200 according to various embodiments of the present disclosure. The second device structure 200 may include a second semiconductor substrate 201 (e.g., a semiconductor wafer) having a first major surface (i.e., a front side surface 202) and a second major surface (i.e., a backside surface 203). A plurality of devices (not shown in FIG. 2) may be disposed on, over and/or in the front side surface 202 of the second semiconductor substrate 201. The second device structure 200 may also include a second interconnect structure 205 over the front side surface 202 of the second semiconductor substrate 201. The second interconnect structure 205 may include metal features 207 (e.g., metal lines, vias, bonding pads, etc.) formed within a dielectric material 206. In some embodiments, the second device structure 200 may also include one or more second through-substrate vias (TSVs) 214 extending through the second semiconductor substrate 201. The second semiconductor substrate 201, second interconnect structure 205 and second TSVs 214 of the second device structure 200 may be similar or identical to the first semiconductor substrate 101, first interconnect structure 105 and first TSVs 114 of the first device structure 100 described above with reference to FIG. 1. Thus, repeated discussion of like elements is omitted for brevity. The second device structure 200 may include one or more unit areas (UAs) as described above. In various embodiments, each of the UA(s) of the second device structure 200 may have an equivalent size and shape as a corresponding UA of the first device structure 100.

The second device structure 200 may further include a second bonding layer 209 including one or more dielectric material layers 108 with second metal bonding features 210, 210a (i.e., bonding pads 210 and bonding vias 213) formed within the one or more dielectric material layers 108 of the second bonding layer 209. The second bonding layer 209 may be located over the backside surface 203 of the second semiconductor substrate 201. At least some of the bonding pads 211 of the second metal bonding features 210, 210a of the second bonding layer 209 may be electrically coupled to second TSVs 214 extending through the second semiconductor substrate 201.

In various embodiments, the layout of the second metal bonding features 210, 210a of the second bonding layer 209 may correspond to the layout of the first metal bonding features 110, 110a of the first bonding layer 109. At least a portion of the second metal bonding features 210, 210a may be “dummy” second metal bonding features 210a that may be located outside of the UA(s) of the second device structure 200.

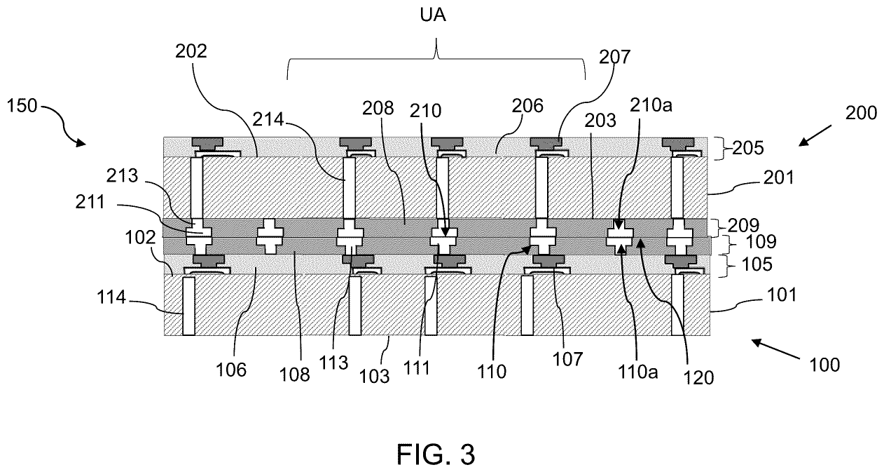

FIG. 3 is a vertical cross-section view illustrating the second device structure 200 bonded to the first device structure 100 to form a bonded device structure 150 according to various embodiments of the present disclosure. Referring to FIG. 3, the second device structure 200 may be aligned over the first device structure 100 such that the second bonding layer 209 on the second device structure 200 faces the first bonding layer 109 on the first device structure 100. Each UA of the second device structure 200 may be aligned over a corresponding UA of the first device structure 100. Each bonding pad 211 of the second metal features 210, 210a of the second bonding layer 209 may be aligned with a corresponding bonding pad 111 of the first metal features 110, 110a of the first bonding layer 109.

Referring again to FIG. 3, in various embodiments, the second bonding layer 209 may be bonded to the first bonding layer 109 via a metal-to-metal (M-M) and dielectric-to-dielectric (D-D) direct bonding technique to couple the second device structure 200 mechanically and electrically to the first device structure 100. In some embodiments, prior to bonding the second device structure 200 to the first device structure 100, the surfaces of the first bonding layer 109 on the first device structure 100 and/or the second bonding layer 209 on the second device structure 200 may optionally be subjected to a pre-treatment process (e.g., a plasma treatment process) to promote surface activation of the first bonding layer 109 and/or the second bonding layer 209 prior to bonding the second device structure 200 to the first device structure 100. To perform the bonding process, the second device structure 200 and the first device structure 100 may be brought together such that the second bonding layer 209 of the second device structure 200 contacts the first bonding layer 109 of the first device structure 100. The second device structure 200 and the first device structure 100 may be aligned such that bonding pads 211 of the first metal bonding features 210, 210a second bonding layer 209 contact corresponding bonding pads 111 of the first metal bonding features 110, 110a of the first bonding layer 109 and dielectric material of the second bonding layer 209 contacts dielectric material of the first bonding layer 109. In a direct bonding process, such as a metal-to-metal (M-M) and dielectric-to-dielectric (D-D) bonding process, bringing the first bonding layer 109 and the second bonding layer 209 into contact with one another may result in a pre-bonding process in which chemical bonds (e.g., hydrogen bridge bonds) may form at the planar interface between the dielectric material of the first bonding layer 109 and the dielectric material of the second bonding layer 209. In some embodiments, the pre-bonding process may be performed at ambient temperature (e.g., ˜20° C.). In other embodiments, the pre-bonding process may be performed at an elevated temperature. In some embodiments, a compressive force may be applied to the second device structure 200 and the first device structure 100 during the pre-bonding process. In other embodiments, no compressive force may be applied during the pre-bonding process.

Referring again to FIG. 3, in some embodiments, an annealing process may be performed to complete the bonding of the bonding pads 111 of the first metal features 110, 110a of the first bonding layer 109 to the bonding pads 211 of the second metal features 210, 210a of the second bonding layer 209 according to various embodiments of the present disclosure. The annealing process may be performed at an elevated temperature, such as 100° C. or more, such as between about 150° C. and about 350° C., although lower and higher temperatures may also be utilized. In some embodiments, a compressive force may be applied to the second device structure 200 and the first device structure 100 during the annealing process. In other embodiments, no compressive force may be applied during the annealing process.

Following the bonding process, the bonded device structure 150 may include a second device structure 200 that is mechanically and electronically coupled to a first device structure 100 at a bonding interface 120. In the embodiment of FIG. 3, bonded device structure 150 includes a configuration in which the backside surface 203 of the second semiconductor substrate 201 of the second device structure 200 is bonded to the front side of the first device structure 100 (i.e., a “back-to-front”configuration). However, it will be understood that other embodiments of the bonded device structure 150 may have a different configuration, such as a front-to-front configuration or a back-to-back configuration. Further, although a metal-to-metal (M-M) and dielectric-to-dielectric (D-D) direct bonding process is described herein, it will be understood that other bonding processes, such as a fusion bonding process, may be used to bond the first device structure 100 and the second device structure 200.

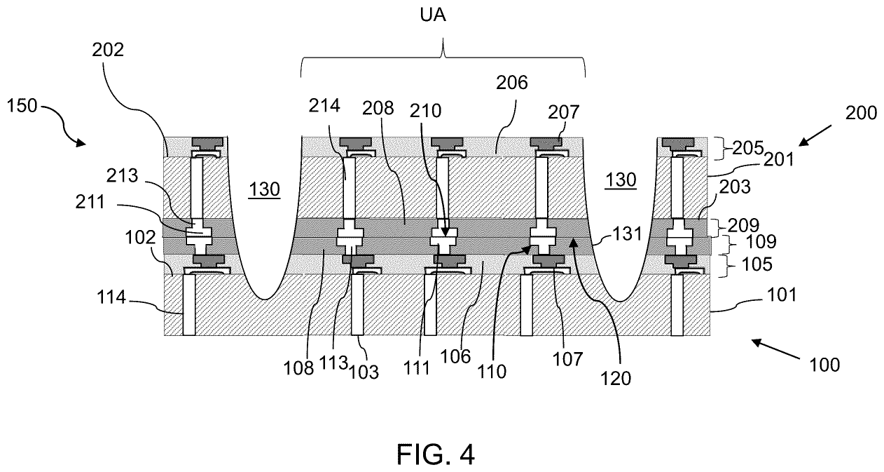

FIG. 4 is a vertical cross-section view of bonded device structure 150 including a plurality of grooves 130 formed in the bonded device structure 150 according to various embodiments of the present disclosure. Referring to FIG. 4, a laser grooving process may be performed to remove portions of the bonded device structure 150 from around the periphery of the unit area(s) UA(s). A laser grooving process may include directing a high-energy laser beam at select regions of the bonded device structure 150, resulting in localized heating and vaporization of the irradiated regions. This may result in the formation of localized trenches or grooves 130 as shown in FIG. 4.

In one non-limiting embodiment, the laser grooving process may utilize a UV laser source, such as 355 nm laser, that may be directed onto select regions of the second device structure 200. The laser may be a pulsed laser having a pulse width between about 110 ns and about 120 ns, a beam diameter of 1 μm or more, and a power between about 5 W and about 10 W. However, it will be understood that other suitable laser sources and laser operating parameters may also be utilized.

In various embodiments, the grooves 130 formed by the laser grooving process may extend through the entire thickness of the second device structure 200, through the bonding interface 120 between the second device structure 200 and the first device structure 100, and into the first device structure 100. That is, the laser grooving process may remove portions of the second interconnect structure 205, the second semiconductor substrate 201, the second bonding layer 209 and the first bonding layer 109, and may optionally also remove portions of the first interconnect structure 105 and the first semiconductor substrate 101. The bonding interface 120 between the second device structure 200 and the first device structure 100 may be exposed along the sidewalls 131 of the grooves 130. In some embodiments, a maximum width of each of the grooves 130 may be between about 50-200 μm, although greater and lesser widths of the grooves 130 are within the contemplated scope of this disclosure.

The grooves 130 may laterally surround the UAs of the bonded device structure 150. The laser grooving process may “precut” the individual UAs prior to performing a final dicing process through the entire thickness of the bonded device structure 150 to form individual bonded die structures. Performing a precut of the UAs prior to final dicing may enable a cleaner dicing process with fewer sawing defects. Further, by providing grooves 130 that extend beyond the bonding interface 120 between the second device structure 200 and the first device structure 100, the final dicing process through the remaining portions of the bonded device structure 150 may result in reduced mechanical stress, which may decrease the occurrence of delamination defects between the first device structure 100 and the second device structure 200 and thereby provide improved reliability and increased yields.

Referring again to FIGS. 3 and 4, in embodiments in which the bonded device structure 150 includes “dummy” first metal bonding features 110a and/or second metal bonding features 210a that are located outside of the UA(s), the “dummy” first metal bonding features 110a and/or second metal bonding features 210a may facilitate the laser grooving process due to the relatively high absorption rate of laser radiation of the metal material(s) of the first metal bonding features 110a and/or second metal bonding features 210a as compared to the surrounding materials, such as dielectric and/or semiconductor materials, of the bonded device structure 150. Thus, the presence of the “dummy” first metal bonding features 110a and/or second metal bonding features 210a within the scribe lanes of the bonded device structure may aid in forming deep grooves that may extend to a depth beyond the bonding interface 120 between the first device structure 100 and the second device structure 200. During the laser grooving process, the “dummy” first metal bonding features 110a and/or second metal bonding features 210a may be burned off. However, remnants of the “dummy” bonding features 110a, 210a, such as copper ions or other metal ions, may be present along the sidewalls 131 of the grooves 130. In some embodiments, the sidewalls 131 of the grooves 130 may include at least about 1 part per billion (ppb) of copper and/or other metal ions as measured using energy dispersive X-ray spectroscopy.

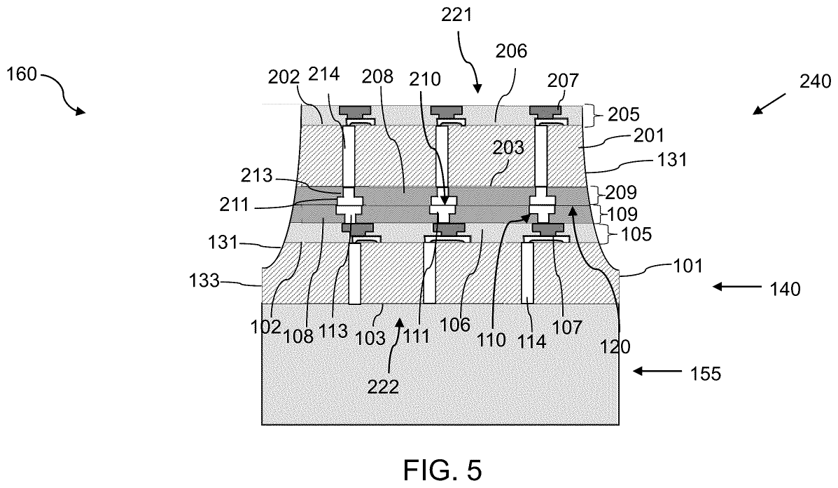

FIG. 5 is a vertical cross-section view of a bonded die structure 160 according to various embodiments of the present disclosure. Referring to FIG. 5, the bonded device structure 150 illustrated in FIG. 4 may be subjected to a dicing process. In various embodiments, the dicing process may be a mechanical dicing process that utilizes a blade, such as a diamond or carbide blade, to cut (e.g., saw) through the bonded device structure 150. The dicing may occur along the precut grooves 130 described above such that individual UAs may be separated from the bonded device structure 150 to provide bonded die structures 160 as shown in FIG. 5. Each bonded die structure 160 may include a first (i.e., front) side 221 and a second (i.e., back) side 222. In the embodiment of FIG. 5, the front side 221 of the bonded die structure 160 may be defined by the upper surface of the second interconnect structure 205. The back side 222 of the bonded die structure 160 may be defined by the back side 103 of the first semiconductor substrate 101. The bonded die structure 160 may have at least one side surface 133 extending from the back side 222 of the bonded die structure 160 towards the front side 221 of the bonded die structure 160, and at least one sidewall 131 extending from a side surface 133 to the front side 221 of the bonded die structure 160. The at least one side surface 133 may be a generally planar surface that may extend in a vertical direction (i.e., perpendicular to the front side 221 and the back side 222 of the bonded die structure 160. The at least one sidewall 131 may be a non-planar contoured surface. In the embodiment of FIG. 5, the at least one sidewall 131 may have a concave curved shape in a vertical cross-section view. The bonded die structure 160 may have an inwardly tapered shape along the at least one sidewall 131 such that a lateral width of the bonded die structure 160 at the front side 221 may be less than the lateral width at the back side 222 of the bonded die structure 160 and along the at least one side surface 133 of the bonded die structure 160.

Referring again to FIG. 5, the bonded die structure 160 may include a first die 140 and a second die 240 that may be mechanically and optionally electrically coupled across a bonding interface 120. The first die 140 and the second die 240 may each include any type of die, including a functional die (e.g., a logic die, a memory die, an analog die, an RF die, an integrated passive device (IPD) die, etc., including various combinations thereof). In other embodiments, one or both of the first die 140 and the second die 240 may be a non-functional or “dummy” die that may provide in-line process structure uniformity and/or routing of electrical signals. In various embodiments, the bonding interface 120 between the first die 140 and the second die 240 may be exposed along the sidewall(s) 131 of the bonded die structure 160. In some embodiments, at least about 1 ppb of copper ions and/or other metal ions may be present on the sidewall(s) 131 of the bonded die structure 160. In some embodiments, at least about 1 ppb of copper ions and/or other metal ions may be present on the sidewall(s) 131 of the bonded die structure 160 on either side of the bonding interface 120 between the first die 140 and the second die 240. As noted above, the copper ions and/or other metal ions may be located on the sidewall(s) 131 following the laser grooving process as evidence of the remnants of the dummy” bonding features 110a, 210a, that have burned off.

The bonded die structure 160 may be located on a carrier structure 155. The carrier structure 155 may include a suitable substrate (e.g., a semiconductor substrate, an organic substrate, a glass substrate, a ceramic substrate, etc.) that may be configured to support the bonded die structure 160. In various embodiments, the back side 222 of the bonded die structure 160 may be bonded or adhered to the carrier structure 155 via a suitable bonding method (e.g., an above-described direct bonding/fusion bonding method) and/or using a suitable adhesive. In one non-limiting embodiment, the bonded die structure 160 may be bonded or adhered to a semiconductor (e.g., silicon) carrier wafer, and a separate dicing process may be used to separate out the portion of the semiconductor carrier wafer on which the bonded die structure 160 is located to provide a bonded die structure 160 on a carrier structure 155 as shown in FIG. 5.

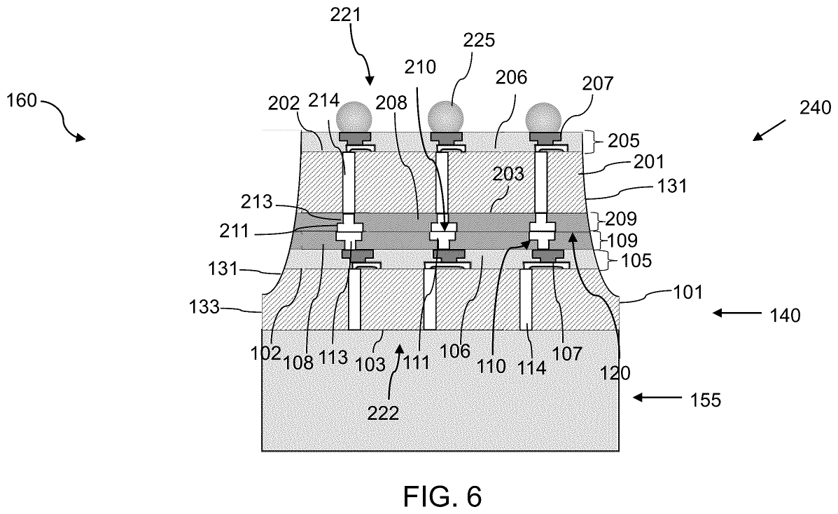

FIG. 6 is a vertical cross-section view of a bonded die structure 160 including a plurality of solder balls 225 over the front side 221 of the bonded die structure 160 according to various embodiments of the present disclosure. Referring to FIG. 6, a plurality of solder balls 225 may be provided on the front side 221 of the bonded die structure 160. Each of the solder balls 225 may contact a metal feature 211 (e.g., a bonding pad) of the second interconnect structure 205 of the bonded die structure 160.

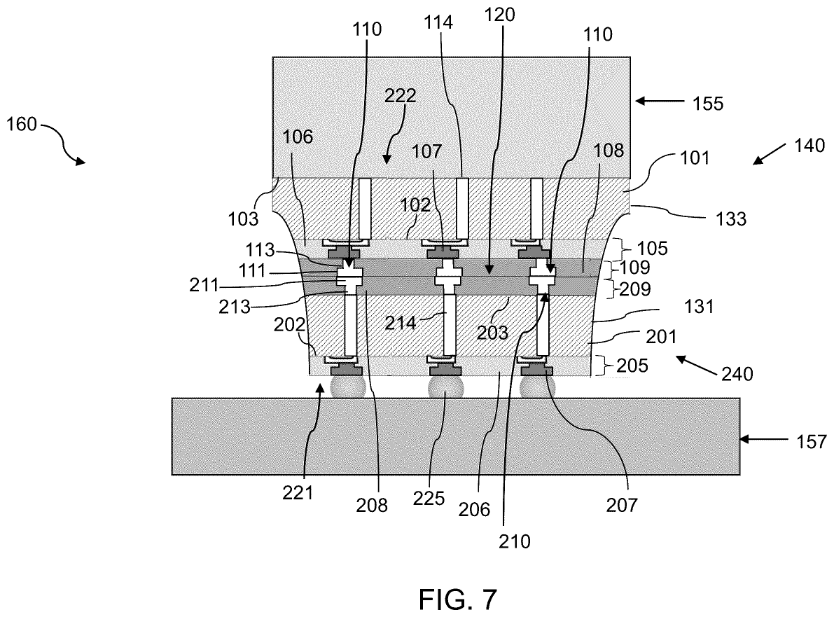

FIG. 7 is a vertical cross-section view showing the bonded die structure 160 on a support structure 157 according to various embodiments of the present disclosure. Referring to FIG. 7, the bonded die structure 160 may be inverted (i.e., flipped over) relative to its orientation as shown in FIG. 6 such that the front side 221 of the bonded die structure 160 faces downwards and the back side of the carrier structure 157 faces upwards. The bonded die structure 160 may be aligned over a support structure 157. The support structure 157 may include, for example, a semiconductor wafer, an interposer, and/or a substrate (e.g., a semiconductor, a glass, or an organic substrate) that may be configured to support the bonded die structure 160. The bonded die structure 160 may be brought into contact with the support structure 157 such that the solder balls 225 may contact corresponding bonding structures (e.g., bonding pads) on the surface of the support structure 157. A reflow process may be used to bond the bonded die structure 160 to the support structure 157.

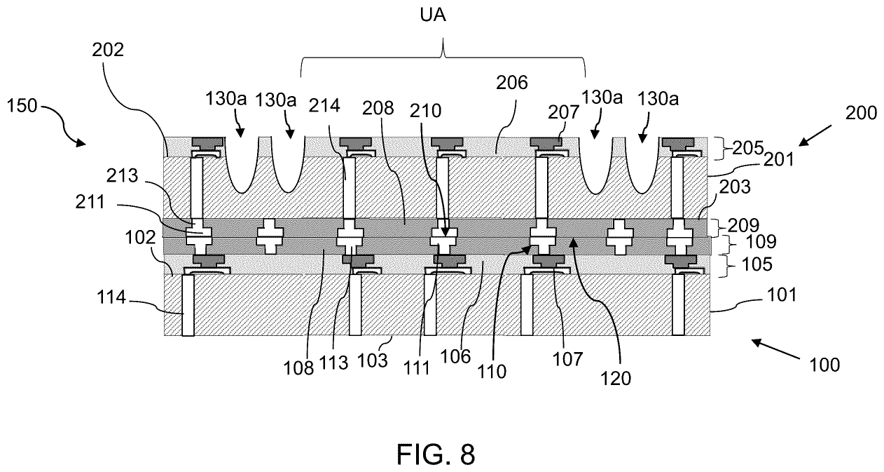

FIG. 8 is a vertical cross-section view of a bonded device structure 150 illustrating a plurality of first grooves 130a formed in the bonded device structure 150 according to another embodiment of the present disclosure. In some embodiments, the laser grooving process on the bonded device structure 150 may be a multi-stage process that may include forming first grooves 130a in the bonded device structure 150 followed by the formation of second grooves in the bonded device structure 150. Referring to FIG. 8, an initial laser grooving process may be performed to produce first grooves 130a around the periphery of the unit area(s) UA(s). In some embodiments, the initial laser grooving process may include forming multiple first grooves 130a within the scribe lanes of the bonded device structure 150. The multiple first grooves 130a may be laterally separated from one another. The initial laser grooving process may include directing laser radiation onto two or more different locations within the scribe lanes simultaneously (e.g., using two different laser sources) or in sequence. FIG. 8 illustrates an embodiment in which a pair of first grooves 130a are formed within the scribe lanes surrounding each of the UAs. However, it will be understood that more than two first grooves 130a or a single first groove 130a may be formed in various embodiments.

In the embodiment of FIG. 8, each of the first grooves 130a extends into the second device structure 200, including into the second interconnect structure 205 and optionally through the second interconnect structure 205 and into the second semiconductor substrate 201. In some embodiments, the first grooves 130a may extend through the second semiconductor substrate 201 and into the second bonding layer 209. In the embodiment of FIG. 8, the first grooves 130a do not extend beyond the bonding interface 120 between the first device structure 100 and the second device structure 200. However, in other embodiments, the first grooves 130a may extend beyond the bonding interface 120 between the first device structure 100 and the second device structure. In the embodiment shown in FIG. 8, each of the first grooves 130a may have equivalent width dimensions and may extend into the bonded device structure 150 to an equivalent depth. However, in other embodiments, the first grooves 130a may have non-uniform width and/or depth dimensions. The first grooves 130a may straddle or laterally surround the dummy” bonding features 110a, 210a.

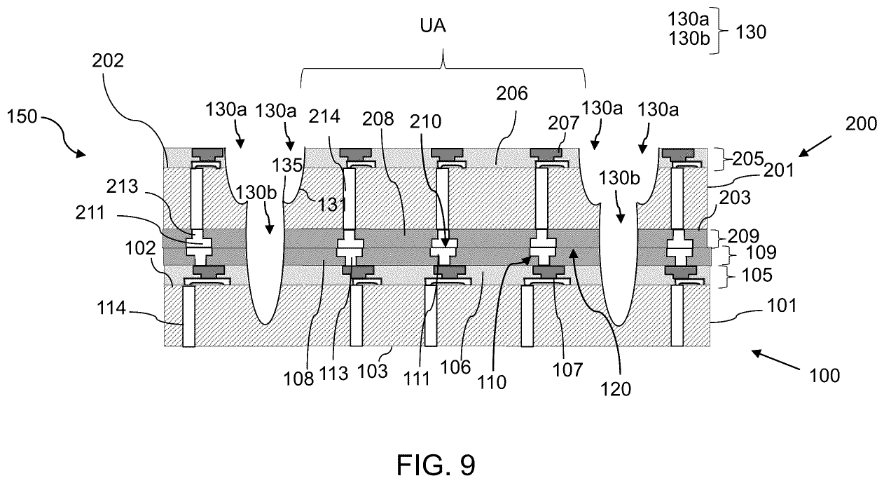

FIG. 9 is a vertical cross-section view of a bonded device structure 150 including second grooves 130b formed in the bonded device structure 150 according to another embodiment of the present disclosure. Referring to FIG. 9, an additional laser grooving process may be performed to produce second grooves 130b around the periphery of the unit area(s) UA(s). The additional laser grooving process may include directing laser radiation onto a location between adjacent pairs of first grooves 130a. The additional laser grooving process may remove material from between the pairs of first grooves 130a so that the first grooves 130a may be connected with one another. The additional layer grooving process may form a second groove 130b located between and connected with the first grooves 130a, where the second groove 130b may have a depth that is greater than the depths of the first grooves 130a. In various embodiments, the second groove 130b may extend through the bonding interface 120 between the second device structure 200 and the first device structure 100 and into the first device structure 100.

In some embodiments, the additional laser grooving process that is used to form the second groove 130b may utilize different parameters (e.g., different laser spot size, different laser power, etc.) than the parameters used during the initial laser grooving process that was used to form the first grooves 130a. In some embodiments, the width dimension of the second groove 130b may be different than the width dimensions of the first grooves 130a.

Referring again to FIG. 9, each pair of adjacent first grooves 130a and the second groove 130b formed between them may together form a continuous groove 130 that may laterally surround each UA of the bonded device structure. The bonding interface 120 between the second device structure 200 and the first device structure 100 may be exposed along the sidewalls 131 of the continuous groove 130. The sidewalls 131 of the continuous groove 130 may also include a discontinuous ridge feature 135 where the second groove 130b meets the adjacent first grooves 130a.

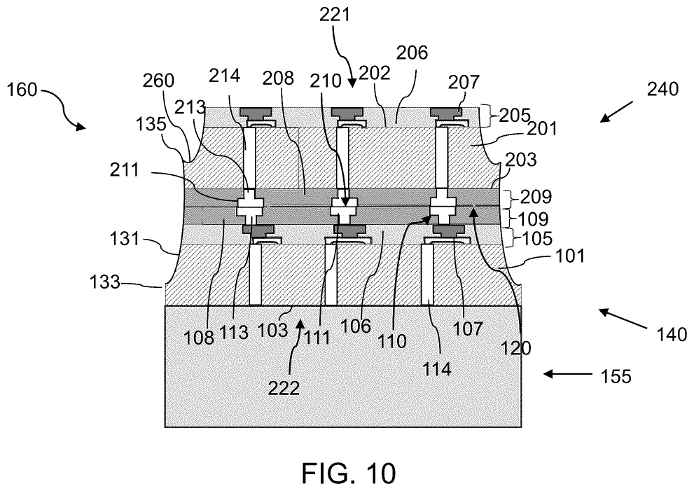

FIG. 10 is a vertical cross-section view of a bonded die structure 160 according to another embodiment of the present disclosure. The bonded die structure 160 may be similar to the bonded die structure 160 described above with reference to FIG. 5. Thus, repeated discussion of like elements is omitted for brevity. The bonded device structure 150 shown in FIG. 9 may be subjected to an above-described dicing process along the grooves 130 such that individual UAs may be separated to provide bonded die structures 160. FIG. 10 illustrates a bonded die structure 160 disposed on an above-described carrier structure 155.

Referring to FIG. 10, the bonded die structure 160 may have at least one side surface 133 extending from the back side 222 of the bonded die structure 160 towards the front side 221 of the bonded die structure 160, and at least one sidewall 131 extending from a side surface 133 to the front side 221 of the bonded die structure 160. The at least one side surface 133 may be a generally planar surface that may extend in a vertical direction (i.e., perpendicular to the front side 221 and the back side 222 of the bonded die structure 160). The at least one sidewall 131 may be a non-planar contoured surface. The bonding interface 120 between the first die 140 and the second die 240 of the bonded die structure 160 may be exposed along the at least one sidewall 131. In the embodiment of FIG. 10, the at least one sidewall 131 may have a discontinuous ridge feature 135. In a vertical cross-section view, the at least one sidewall 131 may have a concave curved shape between the discontinuous ridge feature 135 and the front side 221 of the bonded die structure 150 and a concave curved shape between the discontinuous ridge feature 135 and the side surface 133 of the bonded die structure 160. The discontinuous ridge feature 135 may resemble a geometric cusp in a vertical side cross-section view. As shown in FIG. 10, in some embodiments the discontinuous ridge feature 135 may form a localized elevated region of the sidewall 131 such that the discontinuous ridge feature 135 may be located closer to the plane containing the front side 221 of the bonded die structure 160 than the surrounding portions of the sidewall 131 located on either side of the discontinuous ridge feature 135. In some embodiments, the magnitude of the slope of the at least one sidewall 131 may initially decrease moving from the front side 221 of the bonded die structure 150 towards the back side 222 of the bonded die structure 222. As shown in FIG. 10, the magnitude of the slope of the at least one sidewall 131 may decrease to zero between the front side 221 and the discontinuous ridge feature 135, and may be zero at a local minimum point 260 between the front side 221 and the discontinuous ridge feature 135. The magnitude of the slope may then increase between the local minimum point 260 and the discontinuous ridge feature 135.

In the embodiment of FIG. 10, the discontinuous ridge feature 135 is located between the front side 221 of the bonded die structure 160 and the bonding interface 120 between the first die 140 and the second die 240 (i.e., the discontinuous ridge feature is adjacent to the second die 240). In other embodiments, as described in further detail below, the discontinuous ridge feature 135 may located between the bonding interface 120 and the side surface 133 of the bonded die structure 160 (i.e., the discontinuous ridge feature 135 is adjacent to the first die 140).

In some embodiments, at least about 1 ppb of copper ions and/or other metal ions may be present on the sidewall(s) 131 of the bonded die structure 160. In some embodiments, at least about 1 ppb of copper ions and/or other metal ions may be present on the sidewall(s) 131 of the bonded die structure 160 on either side of the bonding interface 120 between the first die 140 and the second die 240.

In some embodiments, the bonded die structure 160 as shown in FIG. 10 may be inverted and mounted to a suitable support structure 157 via solder balls 225 as described above with reference to FIGS. 6 and 7.

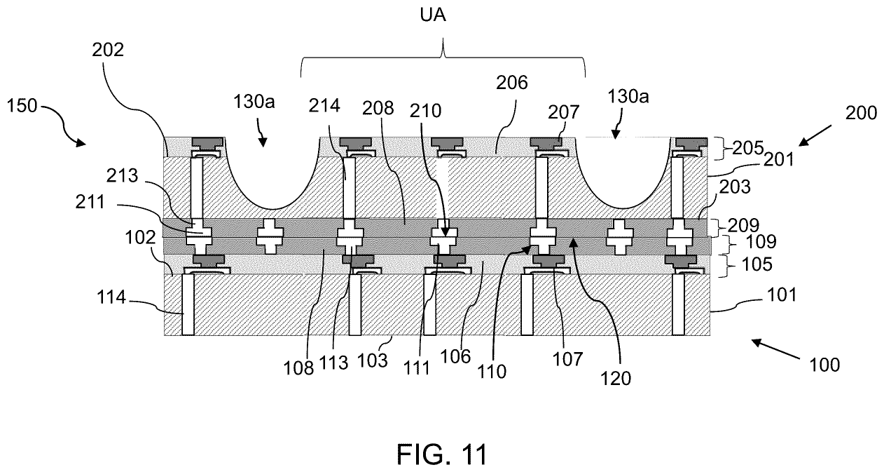

FIG. 11 is a vertical cross-section view of a bonded device structure 150 including first grooves 130a formed in the bonded device structure 150 according to another embodiment of the present disclosure. Referring to FIG. 11, an initial laser grooving process may be performed to produce first grooves 130a around the periphery of the unit area(s) UA(s) of the bonded device structure 150. The initial laser grooving process in the embodiment of FIG. 11 may differ from the initial laser grooving process shown in FIG. 8 in that only a single first groove 130a may be formed in the scribe lanes surrounding each UA. Each of the first grooves 130a may extend into the second device structure 200, including into the second interconnect structure 205 and optionally through the second interconnect structure 205 and into the second semiconductor substrate 201. In some embodiments, the first grooves 130a may extend through the second semiconductor substrate 201 and into the second bonding layer 209. In the embodiment of FIG. 11, the first grooves 130a do not extend beyond the bonding interface 120 between the first device structure 100 and the second device structure 200. However, in other embodiments, the first grooves 130a may extend beyond the bonding interface 120 between the first device structure 100 and the second device structure.

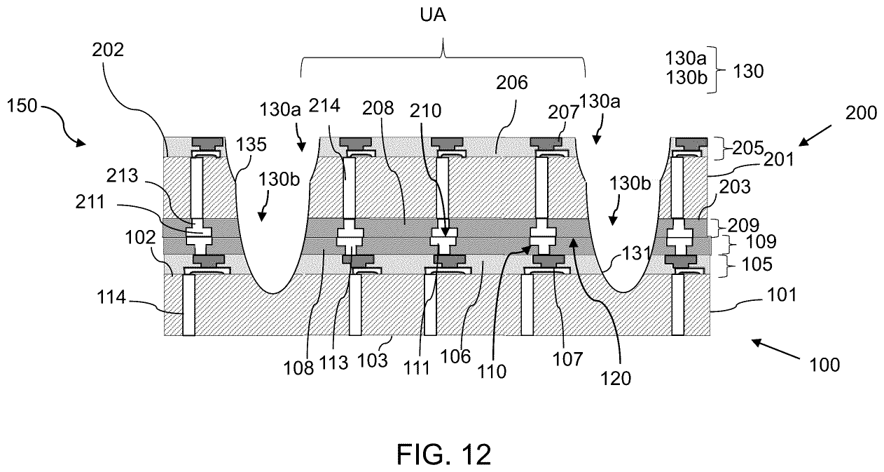

FIG. 12 is a vertical cross-section view of a bonded device structure 150 including second grooves 130b formed in the bonded device structure 150 according to another embodiment of the present disclosure. Referring to FIG. 12, an additional laser grooving process may be performed to produce second grooves 130b around the periphery of the unit area(s) UA(s). The additional laser grooving process may include directing laser radiation onto the locations of the first grooves 130a to form second grooves 130b extending from the bottom surfaces of the respective first grooves 130a. In various embodiments, the second grooves 130b may extend from the bottom surfaces of the first grooves 130a through the bonding interface 120 between the second device structure 200 and the first device structure 100 and into the first device structure 100.

In some embodiments, the additional laser grooving process that is used to form the second grooves 130b may utilize different parameters (e.g., different laser spot size, different laser power, etc.) than the parameters used during the initial laser grooving process that was used to form the first grooves 130a. In some embodiments, the width dimension of the second grooves 130b may be different than the width dimensions of the first grooves 130a. In some embodiments, the width dimensions of the first grooves 130a may be greater than the width dimensions of the second grooves 130b. Forming relatively wider first grooves 130a before forming relatively narrower second grooves 130b may help to minimize stress on the bonded device structure 150 during the laser grooving process.

Referring again to FIG. 12, each first groove 130a and the second groove 130b formed in the bottom surface of the first groove 130a may together form a continuous groove 130 that may laterally surround each UA of the bonded device structure. The bonding interface 120 between the second device structure 200 and the first device structure 100 may be exposed along the sidewalls 131 of the continuous groove 130. The sidewalls 131 of the continuous groove 130 may also include a discontinuous ridge feature 135 where the second groove 130b meets the first groove 130a.

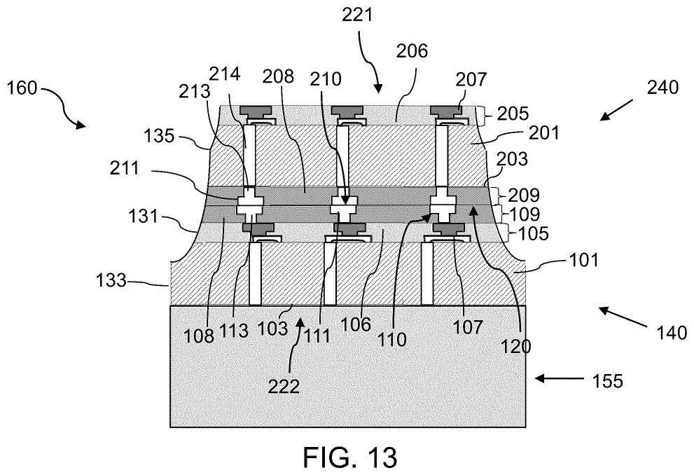

FIG. 13 is a vertical cross-section view of a bonded die structure 160 according to another embodiment of the present disclosure. The bonded die structure 160 may be similar to the bonded die structure 160 described above with reference to FIG. 5. Thus, repeated discussion of like elements is omitted for brevity. The bonded device structure 150 shown in FIG. 13 may be subjected to an above-described dicing process along the grooves 130 such that individual UAs may be separated to provide bonded die structures 160. FIG. 13 illustrates a bonded die structure 160 disposed on an above-described carrier structure 155.

Referring to FIG. 13, the bonded die structure 160 may have at least one side surface 133 extending from the back side 222 of the bonded die structure 160 towards the front side 221 of the bonded die structure 160, and at least one sidewall 131 extending from a side surface 133 to the front side 221 of the bonded die structure 160. The at least one side surface 133 may be a generally planar surface that may extend in a vertical direction (i.e., perpendicular to the front side 221 and the back side 222 of the bonded die structure 160). The at least one sidewall 131 may be a non-planar contoured surface. The bonding interface 120 between the first die 140 and the second die 240 of the bonded die structure 160 may be exposed along the at least one sidewall 131. In the embodiment of FIG. 13, the at least one sidewall 131 may have a discontinuous ridge feature 135. In a vertical cross-section view, the at least one sidewall 131 may have a concave curved shape between the discontinuous ridge feature 135 and the front side 221 of the bonded die structure 150 and a concave curved shape between the discontinuous ridge feature 135 and the side surface 133 of the bonded die structure 160. The discontinuous ridge feature 135 may thus resemble a geometric cusp in vertical side view. In the embodiment of FIG. 13, the discontinuous ridge feature 135 is located between the front side 221 of the bonded die structure 160 and the bonding interface 120 between the first die 140 and the second die 240 (i.e., the discontinuous ridge feature is adjacent to the second die 240). In other embodiments, the discontinuous ridge feature 135 may located between the bonding interface 120 and the side surface 133 of the bonded die structure 160 (i.e., the discontinuous ridge feature 135 is adjacent to the first die 140).

In some embodiments, at least about 1 ppb of copper ions and/or other metal ions may be present on the sidewall(s) 131 of the bonded die structure 160. In some embodiments, at least about 1 ppb of copper ions and/or other metal ions may be present on the sidewall(s) 131 of the bonded die structure 160 on either side of the bonding interface 120 between the first die 140 and the second die 240.

In some embodiments, the bonded die structure 160 as shown in FIG. 13 may be inverted and mounted to a suitable support structure 157 via solder balls 225 as described above with reference to FIGS. 6 and 7.

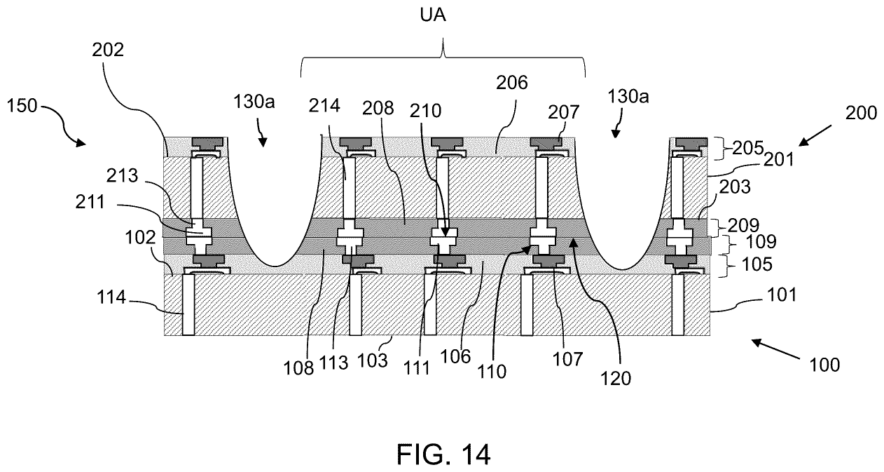

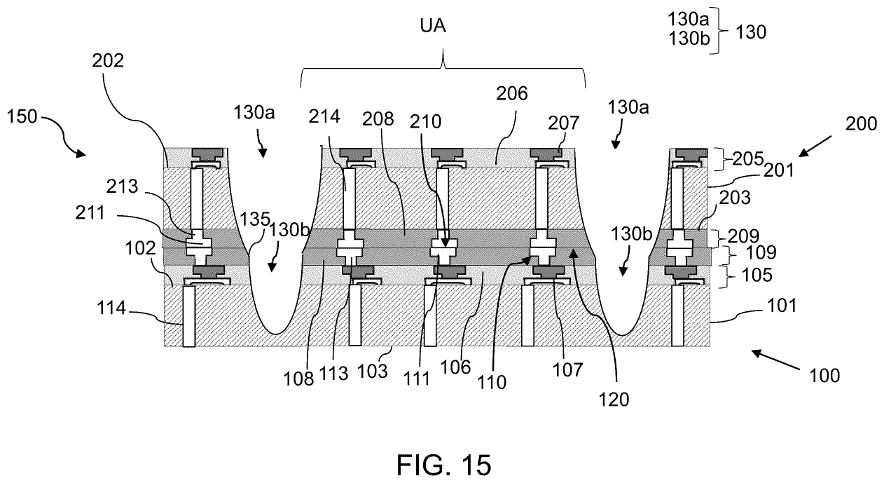

FIG. 14 is a vertical cross-section view of a bonded device structure 150 including first grooves 130a formed in the bonded device structure 150 according to another embodiment of the present disclosure. Referring to FIG. 14, an initial laser grooving process may be performed to produce first grooves 130a around the periphery of the unit area(s) UA(s) of the bonded device structure 150, similar to the first grooves 130a described above with reference to FIG. 11. The initial laser grooving process in the embodiment of FIG. 15 may differ from the initial laser grooving process shown in FIG. 11 the first grooves 130a may extend through the second device structure 200 and the bonding interface 120 between the first device structure 100 and the second device structure 200 and into the first device structure 100.

FIG. 15 is a vertical cross-section view of a bonded device structure 150 including second grooves 130b formed in the bonded device structure 150 according to another embodiment of the present disclosure. Referring to FIG. 15, an additional laser grooving process may be performed to produce second grooves 130b around the periphery of the unit area(s) UA(s). The additional laser grooving process may include directing laser radiation onto the locations of the first grooves 130a to form second grooves 130b extending from the bottom surfaces of the respective first grooves 130a. In various embodiments, the second grooves 130b may extend further into the first device structure 100 than the first grooves 130a.

In some embodiments, the additional laser grooving process that is used to form the second grooves 130b may utilize different parameters (e.g., different laser spot size, different laser power, etc.) than the parameters used during the initial laser grooving process that was used to form the first grooves 130a. In some embodiments, the width dimension of the second grooves 130b may be different than the width dimensions of the first grooves 130a. In some embodiments, the width dimensions of the first grooves 130a may be greater than the width dimensions of the second grooves 130b. Forming relatively wider first grooves 130a before forming relatively narrower second grooves 130b may help to minimize stress on the bonded device structure 150 during the laser grooving process.

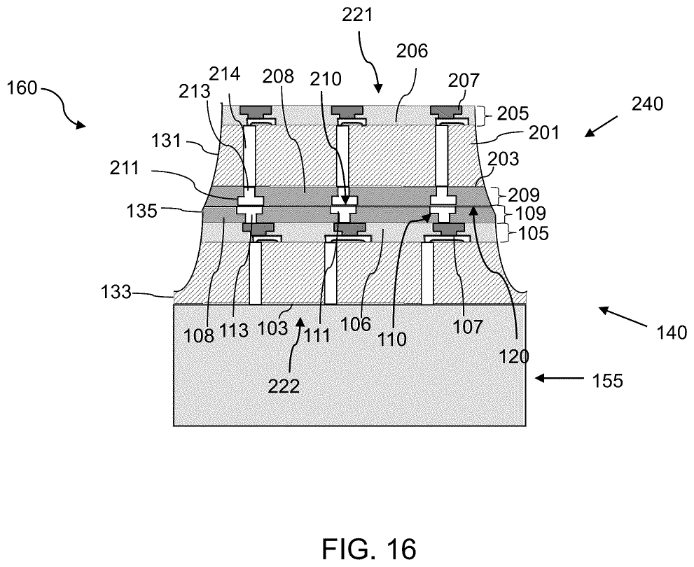

FIG. 16 is a vertical cross-section view of a bonded die structure 160 according to another embodiment of the present disclosure. The bonded die structure 160 may be similar to the bonded die structure 160 described above with reference to FIG. 5. Thus, repeated discussion of like elements is omitted for brevity. The bonded device structure 150 shown in FIG. 13 may be subjected to an above-described dicing process along the grooves 130 such that individual UAs may be separated to provide bonded die structures 160. FIG. 16 illustrates a bonded die structure 160 disposed on an above-described carrier structure 155.

Referring to FIG. 16, the bonded die structure 160 may have at least one side surface 133 extending from the back side 222 of the bonded die structure 160 towards the front side 221 of the bonded die structure 160, and at least one sidewall 131 extending from a side surface 133 to the front side 221 of the bonded die structure 160. The at least one side surface 133 may be a generally planar surface that may extend in a vertical direction (i.e., perpendicular to the front side 221 and the back side 222 of the bonded die structure 160). The at least one sidewall 131 may be a non-planar contoured surface. The bonding interface 120 between the first die 140 and the second die 240 of the bonded die structure 160 may be exposed along the at least one sidewall 131. In the embodiment of FIG. 16, the at least one sidewall 131 may have a discontinuous ridge feature 135. In a vertical cross-section view, the at least one sidewall 131 may have a concave curved shape between the discontinuous ridge feature 135 and the front side 221 of the bonded die structure 150 and a concave curved shape between the discontinuous ridge feature 135 and the side surface 133 of the bonded die structure 160. The discontinuous ridge feature 135 may thus resemble a geometric cusp in vertical side view. In the embodiment of FIG. 16, the discontinuous ridge feature 135 is located between the back side 222 of the bonded die structure 160 and the bonding interface 120 between the first die 140 and the second die 240 (i.e., the discontinuous ridge feature 135 is adjacent to the first die 140).

In some embodiments, at least about 1 ppb of copper ions and/or other metal ions may be present on the sidewall(s) 131 of the bonded die structure 160. In some embodiments, at least about 1 ppb of copper ions and/or other metal ions may be present on the sidewall(s) 131 of the bonded die structure 160 on either side of the bonding interface 120 between the first die 140 and the second die 240.

In some embodiments, the bonded die structure 160 as shown in FIG. 16 may be inverted and mounted to a suitable support structure 157 via solder balls 225 as described above with reference to FIGS. 6 and 7.

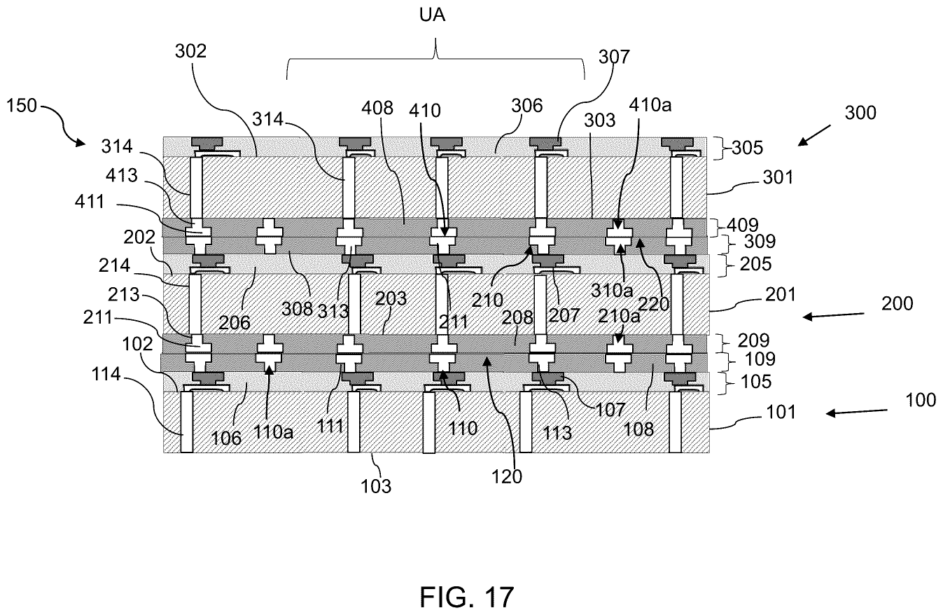

FIG. 17 is a vertical cross-section view illustrating a bonded device structure 150 according to another embodiment of the present disclosure. The bonded device structure 170 of FIG. 17 may be similar to the bonded device structure 150 described above with respect to FIG. 3, and may include a first device structure 100 bonded to a second device structure 200 via respective first and second bonding layers 109 and 209. Thus, repeated discussion of like features is omitted for brevity. The bonded device structure 170 of FIG. 17 differs from the bonded device structure 150 of FIG. 3 in that the bonded device structure 170 of FIG. 17 includes a third device structure 300 bonded to the second device structure 200.

Referring to FIG. 17, the third device structure 300 may be similar to the first device structure 100 and the second device structure 200. The third device structure may include a third semiconductor substrate 301 (e.g., a semiconductor wafer) having a first major surface (i.e., a front side surface 302) and a second major surface (i.e., a backside surface 303), a plurality of devices (not shown in FIG. 17) disposed on, over and/or in the front side surface 302 of the third semiconductor substrate 301, and a third interconnect structure 305 over the front side surface 302 of the third semiconductor substrate 301, where the third interconnect structure 305 may include metal features 307 (e.g., metal lines, vias, bonding pads, etc.) formed within a dielectric material 306. In some embodiments, the third device structure 300 may also include one or more second through-substrate vias (TSVs) 314 extending through the third semiconductor substrate 301. The third device structure 300 may include one or more unit areas (UAs) as described above. In various embodiments, each of the UA(s) of the third device structure 300 may have an equivalent size and shape to corresponding UAs of the first device structure 100 and the second device structure 200.

In various embodiments, a third bonding layer 309 including one or more dielectric material layers 308 with third metal bonding features 310, 310a (i.e., bonding pads 311 and bonding vias 313) formed within the one or more dielectric material layers 308 of the second bonding layer 309 may be formed over the second interconnect structure 205 on the second device structure 200. At least some of the bonding pads 311 of the third metal bonding features 310, 310a of the third bonding layer 309 may be electrically coupled to metal features 207 of the second interconnect structure 205.

A fourth bonding layer 409 including one or more dielectric material layers 408 with fourth metal bonding features 410, 410a (i.e., bonding pads 411 and bonding vias 413) formed within the one or more dielectric material layers 408 of the fourth bonding layer 409 may be formed over the backside surface 303 of the third semiconductor substrate 301 of the third device structure 300. At least some of the bonding pads 411 of the fourth metal bonding features 410, 410a of the fourth bonding layer 409 may be electrically coupled to third TSVs 314 extending through the third semiconductor substrate 301.

In various embodiments, the layout of the third metal bonding features 310, 310a of the third bonding layer 309 may correspond to the layout of the fourth metal bonding features 410, 410a of the fourth bonding layer 409. At least a portion of the third metal bonding features 310, 310a and/or the fourth metal bonding features 410, 410a may be “dummy” second metal bonding features 310a, 410a that may be located outside of the UA(s) of the second device structure 200 and the third device structure 300.

Referring again to FIG. 17, a bonding process, such as metal-to-metal (M-M) and dielectric-to-dielectric (D-D) direct bonding process as described above, may be used to bond the third bonding layer 309 on the second device structure 200 to the fourth bonding layer 409 on the third device structure 300. Following the bonding process, one side of the second device structure 200 may be mechanically and electronically coupled to the first device structure 100 at a first bonding interface 120, and the opposite side of the second device structure 200 may be mechanically and electronically coupled to the third device structure 300 at a second bonding interface 220.

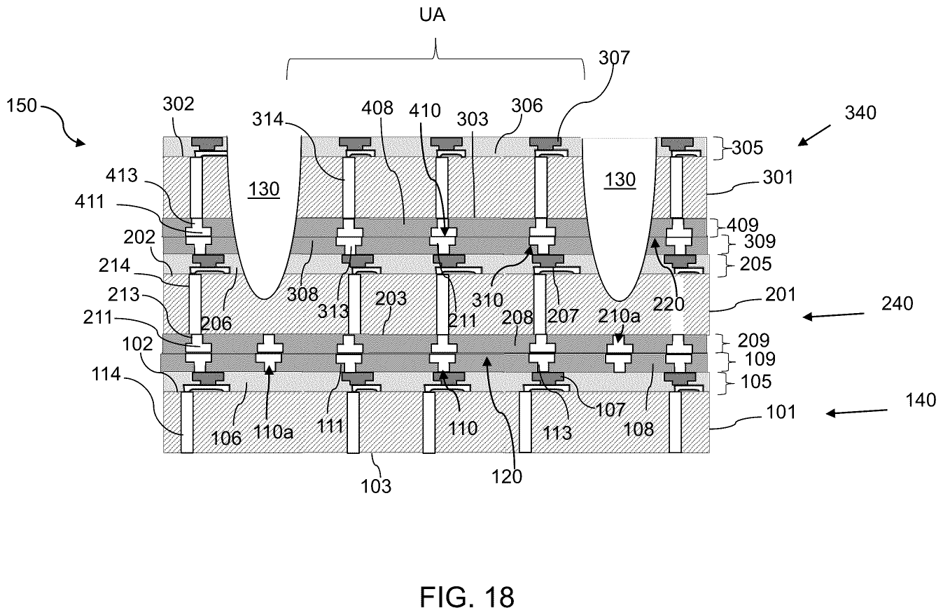

FIG. 18 is a vertical cross-section view of bonded device structure 170 including a plurality of grooves 130 formed in the bonded device structure 170 according to various embodiments of the present disclosure. Referring to FIG. 18, a laser grooving process as described above may be performed to form grooves 130 around the periphery of the unit area(s) UA(s). In various embodiments, the grooves 130 may extend through the third device structure 300 and the second bonding interface 220 and into the second device structure 200. In the embodiment of FIG. 18, the grooves 130 do not extend to or beyond the first bonding interface 120. In some embodiments, the grooves 130 may be formed using a single laser irradiation of the scribe lanes surrounding the UA(s) of the bonded device structure 170. Alternatively, the laser grooving process may be a multi-stage process including multiple laser irradiations forming multiple trenches in each of the scribe lanes, such as described above with reference to FIGS. 8, 9, 11, 12, 14 and 15.

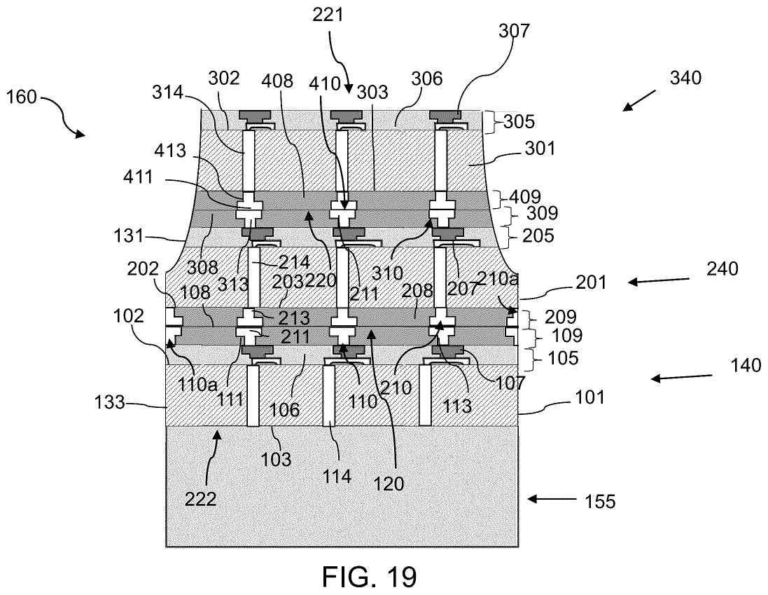

FIG. 19 is a vertical cross-section view of a bonded die structure 170 according to another embodiment of the present disclosure. In various embodiments, the bonded device structure 170 shown in FIG. 18 may be subjected to an above-described dicing process along the grooves 130 such that individual UAs may be separated to provide bonded die structures 160. FIG. 19 illustrates a bonded die structure 170 disposed on an above-described carrier structure 155.

Referring again to FIG. 19, the bonded die structure 170 may include a first die 140, a second die 240, and a third die 340. The first die 140 and the second die 240 may be mechanically and optionally electrically coupled across a first bonding interface 120 and the second die 240 and the third die 340 may be mechanically and optionally electrically coupled across a second bonding interface 220. The first die 140, the second die 240 and the third die 340 may each include any type of die, including a functional die (e.g., a logic die, a memory die, an analog die, an RF die, an integrated passive device (IPD) die, etc., including various combinations thereof). In other embodiments, one or more of the first die 140, the second die 240 and the third die 340 may be a non-functional or “dummy” die that may provide in-line process structure uniformity and/or routing of electrical signals.

The bonded die structure 170 may include a front side 221 defined by the upper surface of the third interconnect structure 305, and a back side 222 defined by the back side 103 of the first semiconductor substrate 101. The bonded die structure 170 may have at least one side surface 133 extending from the back side 222 of the bonded die structure 160 towards the front side 221 of the bonded die structure 170, and at least one sidewall 131 extending from a side surface 133 to the front side 221 of the bonded die structure 170. The at least one side surface 133 may be a generally planar surface that may extend in a vertical direction (i.e., perpendicular to the front side 221 and the back side 222 of the bonded die structure 170. The at least one sidewall 131 may be a non-planar contoured surface. In the embodiment of FIG. 19, the at least one sidewall 131 may have a concave curved shape in a vertical cross-section view. In embodiments in which a multi-stage laser grooving process is utilized, the at least one sidewall 131 of the bonded die structure 170 may include a discontinuous ridge feature 135 as shown in FIGS. 10, 13 and 16. The bonded die structure 170 may have an inwardly tapered shape along the at least one sidewall 131 such that a lateral width of the bonded die structure 170 at the front surface 221 may be less than the lateral width at the back surface 222 of the bonded die structure 170 and along the at least one side surface 133 of the bonded die structure 170.

In various embodiments, the second bonding interface 220 between the third die 340 and the second die 240 may be exposed along the sidewall(s) 131 of the bonded die structure 170. In the embodiment of FIG. 19, the first bonding interface 120 between the second die 240 and the first die 140 may be exposed along the side surface 133 of the bonded die structure 170. In some embodiments, at least about 1 ppb of copper ions and/or other metal ions may be present on the sidewall(s) 131 of the bonded die structure 170. In some embodiments, at least about 1 ppb of copper ions and/or other metal ions may be present on the sidewall(s) 131 of the bonded die structure 170 on either side of the second bonding interface 220 between the third die 340 and the second die 240.

In some embodiments, the bonded die structure 170 as shown in FIG. 19 may be inverted and mounted to a suitable support structure 157 via solder balls 225 as described above with reference to FIGS. 6 and 7.

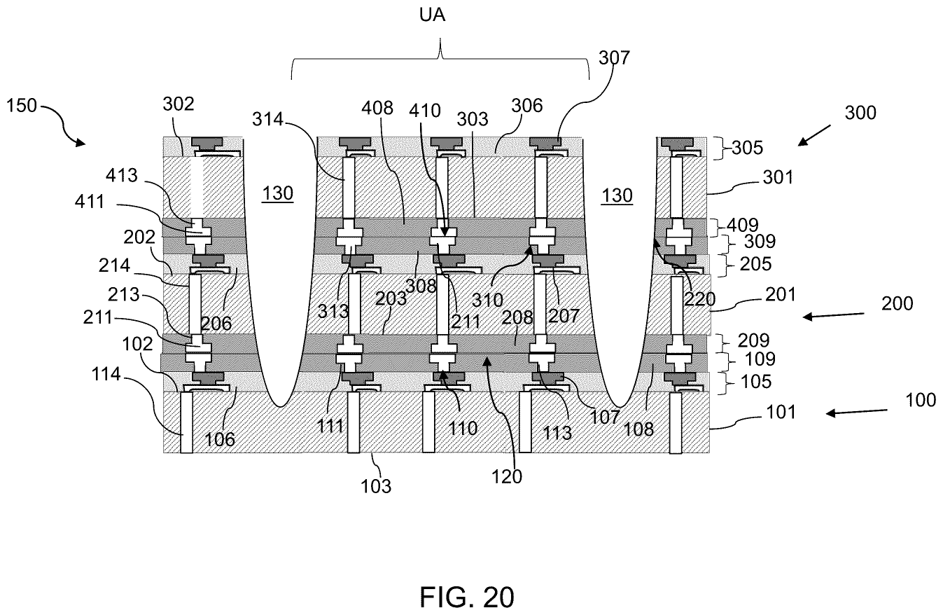

FIG. 20 is a vertical cross-section view of bonded device structure 180 including a plurality of grooves 130 formed in the bonded device structure 180 according to another embodiment of the present disclosure. The bonded device structure 180 of FIG. 20 may be similar to the bonded device structure 170 described above with reference to FIGS. 17 and 18. Thus, repeated discussion of like features is omitted for brevity. The bonded device structure 180 of FIG. 20 may differ from the bonded device structure 170 of FIG. 18 in that the grooves 130 may extend through the third device structure 300 and the second device structure 200 and into the first device structure 100. Both the second bonding interface 220 between the third device structure 300 and the second device structure 200 and the first bonding interface 120 between the second device structure 200 and the first device structure 100 may be exposed along the sidewalls 131 of the grooves 130. In some embodiments, the grooves 130 may be formed using a single laser irradiation of the scribe lanes surrounding the UA(s) of the bonded device structure 180. Alternatively, the laser grooving process may be a multi-stage process including multiple laser irradiations forming multiple trenches in each of the scribe lanes, such as described above with reference to FIGS. 8, 9, 11, 12, 14 and 15.

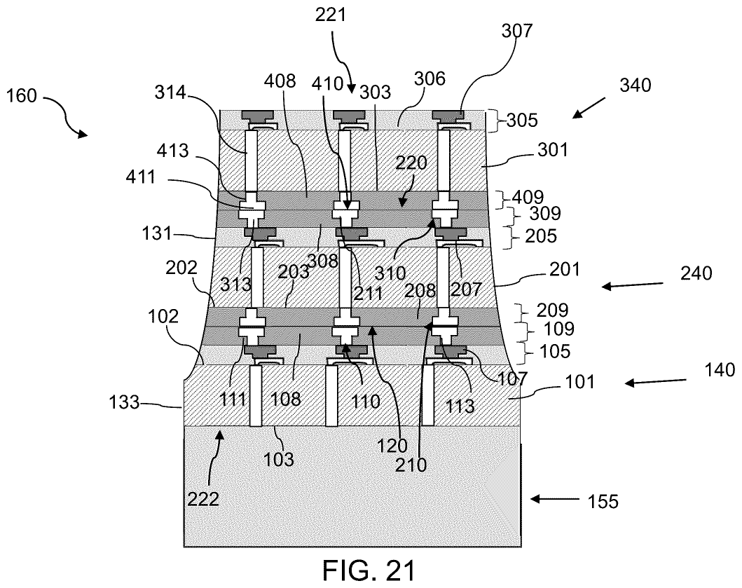

FIG. 21 is a vertical cross-section view of a bonded die structure 180 according to another embodiment of the present disclosure. In various embodiments, the bonded device structure 180 shown in FIG. 21 may be subjected to an above-described dicing process along the grooves 130 such that individual UAs may be separated to provide bonded die structures 180. FIG. 21 illustrates a bonded die structure 180 disposed on an above-described carrier structure 155.

Referring again to FIG. 21, the bonded die structure 180 may have at least one side surface 133 extending from the back side 222 of the bonded die structure 180 towards the front side 221 of the bonded die structure 180, and at least one sidewall 131 extending from a side surface 133 to the front side 221 of the bonded die structure 180. The at least one side surface 133 may be a generally planar surface that may extend in a vertical direction (i.e., perpendicular to the front side 221 and the back side 222 of the bonded die structure 180. The at least one sidewall 131 may be a non-planar contoured surface. In the embodiment of FIG. 21, the at least one sidewall 131 may have a concave curved shape in a vertical cross-section view. In embodiments in which a multi-stage laser grooving process is utilized, the at least one sidewall 131 of the bonded die structure 180 may include a discontinuous ridge feature 135 as shown in FIGS. 10, 13 and 16.

In various embodiments, both the second bonding interface 220 between the third die 340 and the second die 240 and the first bonding interface 120 between the second die 240 and the first die 140 may be exposed along the sidewall(s) 131 of the bonded die structure 180. In some embodiments, at least about 1 ppb of copper ions and/or other metal ions may be present on the sidewall(s) 131 of the bonded die structure 180. In some embodiments, at least about 1 ppb of copper ions and/or other metal ions may be present on the sidewall(s) 131 of the bonded die structure 180. In some embodiments, at least about 1 ppb of copper ions and/or other metal ions may be present on the sidewall(s) 131 on both sides of the second bonding interface 220 as well as on both sides of the first bonding interface 120.

In some embodiments, the bonded die structure 180 as shown in FIG. 21 may be inverted and mounted to a suitable support structure 157 via solder balls 225 as described above with reference to FIGS. 6 and 7.

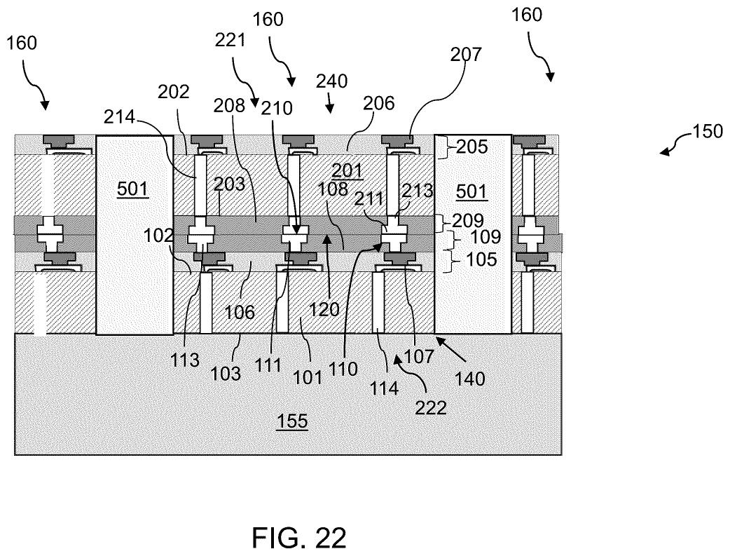

FIG. 22 is a vertical cross-section view illustrating a bonded device structure 195 including a bonded die structure 190 disposed on a carrier structure 155 and laterally surrounded by a gap fill dielectric material 501 according to an embodiment of the present disclosure. Referring to FIG. 22, a bonded die structure 190 including a first die 140 bonded to a second die 240 at a bonding interface 120 may be provided on a carrier structure 155. The bonded die structure 190 and the carrier structure 155 may be similar to any of the bonded die structures 190 and carrier structures 155 described above. In the embodiment of FIG. 22, the bonded die structure 190 is shown having planar side surfaces extending vertically between the front side 221 and the back side 222 of the bonded die structure 190. However, it will be understood that the side surfaces of the bonded die structure 190 may have a shape similar to any of the embodiments described above with reference to FIGS. 5, 10, 13, 16, 19 and/or 21. In some embodiments, a plurality of bonded die structures 190 may be disposed on the carrier structure 155, which may be, for example, a semiconductor wafer. The bonded die structures 190 may be laterally spaced from one another.

A gap fill dielectric material 501 may be deposited on the carrier structure 155 including within the gaps between adjacent bonded die structures 190. The gap fill dielectric material 501 may include a suitable dielectric material, such as silicon oxide, silicon nitride, silicon carbide, silicon oxynitride, silicon carbon nitride, a low-K dielectric material, and extremely low-K (ELK) dielectric material, undoped silicon glass (USG), fluorosilicate glass (FSG), phosphor-silicate glass (PSG), etc., including combinations thereof. Other suitable dielectric materials for the gap fill dielectric material 501 are within the contemplated scope of disclosure. The gap fill dielectric layer 501 may be deposited using a suitable deposition process, such as chemical vapor deposition (CVD) process, a physical vapor deposition (PVD) process, an atomic layer deposition (ALD) process, a high density plasma CVD (HDPCVD) process, a low pressure CVD process, a metalorganic CVD (MOCVD) process, a plasma enhanced CVD (PECVD) process, a sputtering process, laser ablation, or the like. In some embodiments, the gap fill dielectric material 501 may be deposited over the bonded die structures 195 and within the gaps between the bonded die structures 190 and a planarization process, such as a chemical mechanical planarization (CMP) process, may be used to remove excess gap fill dielectric material 501 from over the front surfaces 221 of the bonded die structures 190.

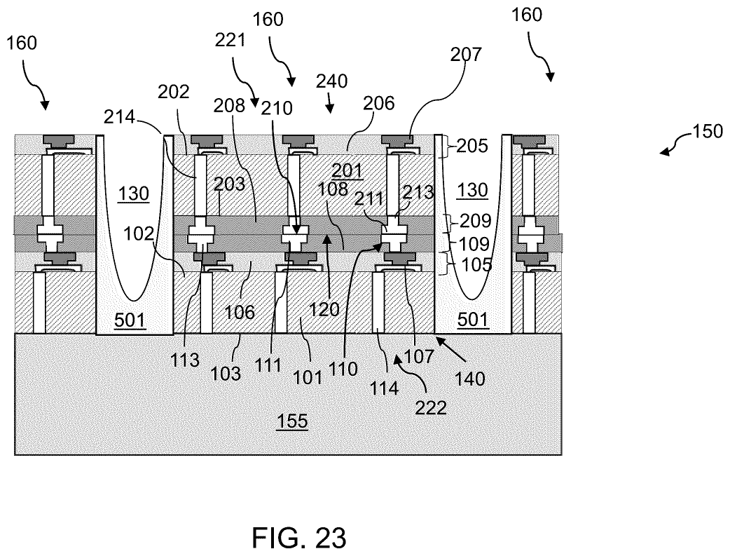

FIG. 23 is a vertical cross-section view of a bonded device structure including a plurality of grooves 130 formed in the gap fill dielectric material 501 according to various embodiments of the present disclosure. Referring to FIG. 23, a laser grooving process may be performed to remove portions of the gap fill dielectric material 501 form grooves 130 in the gap fill dielectric material 501 around the periphery of each of the bonded die structures 190. The gaps 130 may be laterally offset from the peripheral edges of the bonded die structure 190. In various embodiments, the grooves 130 may extend to a depth below the plane containing the bonding interface 120 between the first die 140 and the second die 240.

In some embodiments, the grooves 130 may be formed using a single laser irradiation of the gap fill dielectric material 501 surrounding the bonded die structure(s) 190. Alternatively, the laser grooving process may be a multi-stage process including multiple laser irradiations forming multiple trenches surrounding each of the bonded die structures 190, such as described above with reference to FIGS. 8, 9, 11, 12, 14 and 15.

The bonded die structure 190 may include a front side 221 defined by the upper surface of the second interconnect structure 205 and the upper surface of the gap fill dielectric material 501, and a back side 222 defined by the back side 103 of the first semiconductor substrate 101 and the bottom surface of the gap fill dielectric material 501. The bonded die structure 160 may have at least one side surface 133 extending from the back side 222 of the bonded die structure 160 towards the front side 221 of the bonded die structure 160, and at least one sidewall 131 extending from a side surface 133 to the front side 221 of the bonded die structure 160. The at least one side surface 133 may be a generally planar surface that may extend in a vertical direction (i.e., perpendicular to the front side 221 and the back side 222 of the bonded die structure 160. In some embodiments, the at least one side surface 133 may be continuous with corresponding side surface(s) of the carrier structure 155. The at least one sidewall 131 may be a non-planar contoured surface. In the embodiment of FIG. 19, the at least one sidewall 131 may have a concave curved shape in a vertical cross-section view. In embodiments in which a multi-stage laser grooving process is utilized, the at least one sidewall 131 of the bonded die structure 160 may include a discontinuous ridge feature 135 as shown in FIGS. 10, 13 and 16. In various embodiments, at least one side surface 133 and the at least one sidewall 131 of the bonded die structure 150, 160, 170, 180, 190 may be formed by the gap fill dielectric material 501 laterally surrounding the first and second dies 140 and 240. In various embodiments, the plane containing the bonding interface 120 between the first die 140 and the second die 240 may intersect the at least one sidewall 131 of the bonded die structure 150, 160, 170, 180, 190.

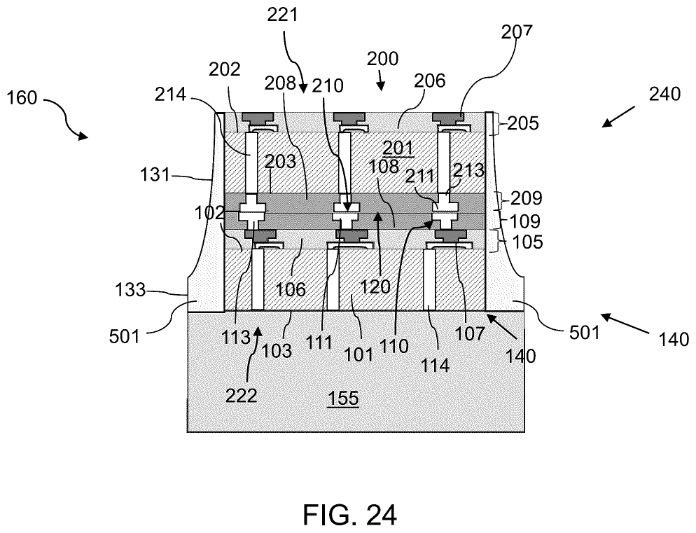

In some embodiments, the bonded die structure 190 as shown in FIG. 24 may be inverted and mounted to a suitable support structure 157 via solder balls 225 as described above with reference to FIGS. 6 and 7.

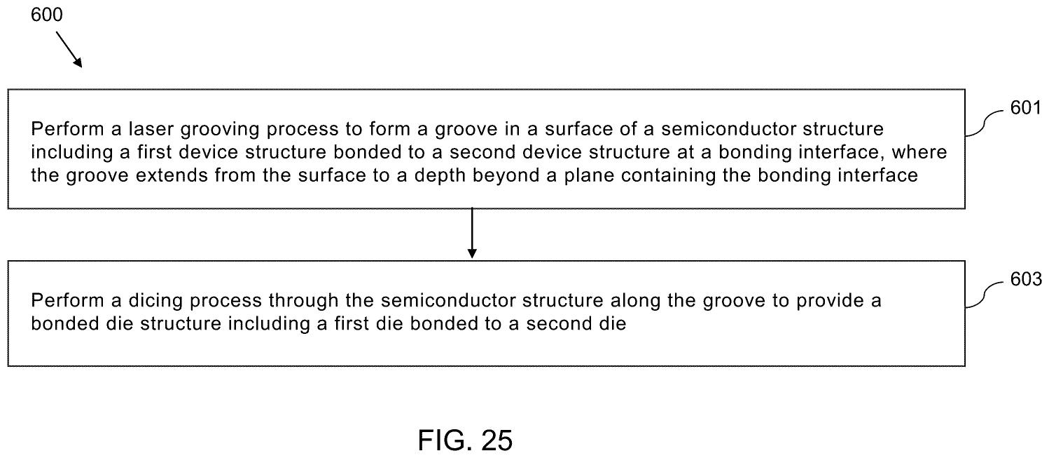

FIG. 25 is a flowchart illustrating a method 600 of fabricating a bonded die structure 150, 160, 170, 180, 190 according to an embodiment of the present disclosure. Referring to FIGS. 4, 8, 9, 11, 12, 14, 15, 18, 20, 23 and 25, in step 601 of method 600, a laser grooving process may be performed to form a groove 130 in a surface 221 of a semiconductor structure 150, 160, 170, 180, 190 including a first device structure 100 bonded to a second device structure 200 at a bonding interface 120, where the groove 130 extends from the surface 221 to a depth beyond a plane including the bonding interface 120. Referring to FIGS. 5, 10, 13, 16, 19, 21, 24 and 25, in step 603 of method 600, a dicing process may be performed through the semiconductor structure 150 along the grove 130 to provide a bonded die structure 150, 160, 170, 180, 190 including a first die 140 bonded to a second die 240.

Referring to all drawings and according to various embodiments of the present disclosure, a bonded die structure 150, 160, 170, 180, 190 includes a first die 140 including a first semiconductor substrate 101, and a second die 240 including a second semiconductor substrate 201, where the first die 140 is bonded to the second die 240 at a bonding interface 120, the bonded die structure 150, 160, 170, 180, 190 includes a sidewall 131 having a non-planar contoured surface, and a plane containing the bonding interface 120 intersects the sidewall 131 of the bonded die structure 160.

In one embodiment, the bonded die structure 150, 160, 170, 180, 190 includes a first side 221 and a second side 222, a planar side surface 133 that extends from the second side 222 towards the first side 221, and the sidewall 131 having the non-planar contoured surface extends between the planar side surface 133 and the first side 221 of the bonded die structure 150, 160, 170, 180, 190.

In another embodiment, the bonded die structure 150, 160, 170, 180, 190 includes an inwardly tapered shape along the sidewall 131 such that a lateral width of the bonded die structure 150, 160, 170, 180, 190 at the first side 221 is less than a lateral width of the bonded die structure 150, 160, 170, 180, 190 along the side surface 133 and at the second side 222 of the bonded die structure 150, 160, 170, 180, 190.

In another embodiment, the sidewall 131 has a concave curved shape between the side surface 133 and the first side 221 of the bonded die structure 150, 160, 170, 180, 190 in a vertical cross-section view.

In another embodiment, the sidewall 131 has a discontinuous ridge feature 135, and the sidewall 131 has a concave curved shape between the discontinuous ridge feature 135 and the first side 221 of the bonded die structure 150, 160, 170, 180, 190, and a concave curved shape between the discontinuous ridge feature 135 and the side surface 133 of the bonded die structure 150, 160, 170, 180, 190 in a vertical cross-section view.

In another embodiment, the discontinuous ridge feature 135 is located between the plane containing the bonding interface 120 and the first side 221 of the bonded die structure 150, 160, 170, 180, 190.

In another embodiment, the discontinuous ridge feature 135 is located between the plane containing the bonding interface 120 and the side surface 133 of the bonded die structure 150, 160, 170, 180, 190.

In another embodiment, the bonded die structure 150, 160, 170, 180, 190 further includes a third die 340 including a third semiconductor substrate 301, where the third die 340 is bonded to the second die 240 via a second bonding interface 220.

In another embodiment, a plane containing the second bonding interface 220 intersects the sidewall 131 of the bonded die structure 150, 160, 170, 180, 190.

In another embodiment, the bonded die structure 150, 160, 170, 180, 190 further includes a gap fill dielectric material 501 laterally surrounding the first die 140 and the second die 240, where the sidewall 131, the side surface 133, a portion of the first side 221, and a portion of the second side 222 of the bonded die structure 150, 160, 170, 180, 190 are formed by the gap fill dielectric material 501.

Another embodiment is drawn to a bonded device structure 150, 160, 170, 180, 190 including a first die 140 including a first semiconductor substrate 101, and a second die 240 including a second semiconductor substrate 201, where the first die 140 is bonded to the second die 240 at a bonding interface 120, the bonded die structure 150, 160, 170, 180, 190 includes a sidewall 131 having a non-planar contoured surface, and the bonding interface 120 between the first die 140 and the second die 240 is exposed along the sidewall 131 of the bonded die structure 150, 160, 170, 180, 190.

In one embodiment, at least 1 ppb of metal ions are present on the sidewall 131 of the bonded die structure 150, 160, 170, 180, 190.

In another embodiment, at least 1 ppb of copper ions are present on the sidewall 131 of the bonded die structure 150, 160, 170, 180, 190 on either side of the bonding interface 120.

In another embodiment, the sidewall 131 includes a discontinuous ridge feature 135 having the shape of a geometric cusp in vertical cross-section view.

Another embodiment is drawn to a method of fabricating a bonded die structure 150, 160, 170, 180, 190 that includes performing a laser grooving process to form a groove 130 in a surface 221 of a semiconductor structure 150, 160, 170, 180, 190 including a first device structure 100 bonded to a second device structure 200 at a bonding interface 120, where the groove 130 extends from the surface 221 to a depth beyond a plane containing the bonding interface 120, and performing a dicing process through the semiconductor structure 150, 160, 170, 180, 190 along the groove 130 to provide a bonded die structure 150, 160, 170, 180, 190 including a first die 140 bonded to a second die 240.

In one embodiment, the method further includes forming a first bonding layer 109 including first metal bonding features 110, 110a formed within a dielectric material 108 on the first device structure 100, forming a second bonding layer 209 including second metal bonding features 210, 210a formed within a dielectric material 208 on the second device structure 200, and bonding the first bonding layer 109 to the second bonding layer 209 to bond the first device structure 100 to the second device structure 200 at the bonding interface 120 between the first bonding layer 109 and the second bonding layer 209, where the groove 130 is formed through at least one dummy first metal bonding feature 110a or second metal bonding feature 210a located in a scribe lane of the semiconductor structure 150, 160, 170, 180, 190.

In another embodiment, forming the groove 130 in the semiconductor structure 150 includes forming a first groove 130a in the semiconductor structure 150, 160, 170, 180, 190 and subsequently forming a second groove 130b that is continuous with the first groove 130a.

In another embodiment, forming the groove 130 in the semiconductor structure 150, 160, 170, 180, 190 includes forming a pair of first grooves 130a in the surface 221 of the semiconductor structure 150, 160, 170, 180, 190 that are laterally spaced from one another, and the second groove 130b is formed between the pair of first grooves 130a.

In another embodiment, forming the groove 130 in the semiconductor structure 150, 160, 170, 180, 190 includes forming the first groove 130a in the surface 221 of the semiconductor structure 150, 160, 170, 180, 190, where the first groove 130a does not extend to the depth of the plane containing the bonding interface 120, and forming the second groove 130b through a bottom surface of the first groove 130a to a depth beyond the plane containing the bonding interface 120.

In another embodiment, forming the groove 130 in the semiconductor structure 150, 160, 170, 180, 190 includes forming the first groove 130a in the surface 221 of the semiconductor structure 150, 160, 170, 180, 190 to a depth beyond the plane containing the bonding interface 120, and forming the second groove 130b through a bottom surface of the first groove 130a.

The various embodiments disclosed herein may provide bonded die structures and methods of forming the same that provide reduced defects and higher reliability. A laser grooving process may be used to “precut” bonded device structures prior to a final dicing process. The laser grooving process may form relatively deep grooves in the bonded device structure that may extend beyond the bonding interface between a first device structure and a second device structure. A final dicing process along the precut grooves may be used to separate individual bonded die structures. Because the dicing occurs along the deep precut grooves that extend through the bonding interface between the stacked device structures, the dicing blade may not cut through or come into contact with the bonding interface. This may result in in reduced mechanical stress, which may decrease the occurrence of delamination defects between the device structures and thereby provide improved reliability and increased yields.

The foregoing outlines features of several embodiments so that those skilled in the art may better understand the aspects of this disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of the present disclosure.

What is claimed is:

1. A structure, comprising:
a first die comprising a first semiconductor substrate; and
a second die comprising a second semiconductor substrate, wherein the first die is bonded to the second die at a bonding interface, the bonded die structure comprises a sidewall having a non-planar contoured surface, and a plane containing the bonding interface intersects the sidewall of the bonded die structure.

2. The structure of claim 1, wherein the bonded die structure comprises a first side and a second side, a planar side surface that extends from the second side towards the first side, and the sidewall having the non-planar contoured surface extends between the planar side surface and the first side of the bonded die structure.

3. The structure of claim 2, wherein the bonded die structure comprises an inwardly tapered shape along the sidewall such that a lateral width of the bonded die structure at the first side is less than a lateral width of the bonded die structure along the side surface and at the second side of the bonded die structure.

4. The structure of claim 3, wherein the sidewall has a concave curved shape between the side surface and the first side of the bonded die structure in a vertical cross-section view.

5. The structure of claim 3, wherein the sidewall has a discontinuous ridge feature, and the sidewall has a concave curved shape between the discontinuous ridge feature and the first side of the bonded die structure, and a concave curved shape between the discontinuous ridge feature and the side surface of the bonded die structure in a vertical cross-section view.

6. The structure of claim 5, wherein the discontinuous ridge feature is located between the plane containing the bonding interface and the first side of the bonded die structure.

7. The structure of claim 5, wherein the discontinuous ridge feature is located between the plane containing the bonding interface and the side surface of the bonded die structure.

8. The structure of claim 1, further comprising:
a third die comprising a third semiconductor substrate, wherein the third die is bonded to the second die via a second bonding interface.

9. The structure of claim 1, wherein a plane containing the second bonding interface intersects the sidewall of the bonded die structure.

10. The bonded die structure of claim 2, further comprising:
a gap fill dielectric material laterally surrounding the first die and the second die, wherein the sidewall, the side surface, a portion of the first side, and a portion of the second side of the bonded die structure are formed by the gap fill dielectric material.

11. A die structure, comprising:
a first die comprising a first semiconductor substrate; and
a second die comprising a second semiconductor substrate, wherein the first die is bonded to the second die at a bonding interface, the bonded die structure comprises a sidewall having a non-planar contoured surface, and the bonding interface between the first die and the second die is exposed along the sidewall of the bonded die structure.

12. The structure of claim 11, wherein at least 1 ppb of metal ions are present on the sidewall of the bonded die structure.

13. The structure of claim 12, wherein at least 1 ppb of copper ions are present on the sidewall of the bonded die structure on either side of the bonding interface.

14. The structure of claim 11, wherein the sidewall comprises a discontinuous ridge feature having a shape of a geometric cusp in vertical cross-section view.

15. A method of fabricating a bonded die structure, comprising:
forming a groove in a surface of a semiconductor structure comprising a first device structure bonded to a second device structure at a bonding interface, wherein the groove extends from the surface to a depth beyond a plane containing the bonding interface; and
performing a process through the semiconductor structure along the groove to provide a bonded die structure comprising a first die bonded to a second die.

16. The method of claim 15, further comprising:
forming a first bonding layer comprising first metal bonding features formed within a dielectric material on the first device structure;
forming a second bonding layer comprising second metal bonding features formed within a dielectric material on the second device structure; and
bonding the first bonding layer to the second bonding layer to bond the first device structure to the second device structure at the bonding interface between the first bonding layer and the second bonding layer, wherein the groove is formed through at least one dummy first metal bonding feature or second metal bonding feature located in a scribe lane of the semiconductor structure.

17. The method of claim 15, wherein forming the groove in the semiconductor structure comprises forming a first groove in the semiconductor structure and subsequently forming a second groove that is continuous with the first groove.

18. The method of claim 17, wherein forming the groove in the semiconductor structure comprises forming a pair of first grooves in the surface of the semiconductor structure that are laterally spaced from one another, and the second groove is formed between the pair of first grooves.

19. The method of claim 17, wherein forming the groove in the semiconductor structure comprises forming the first groove in the surface of the semiconductor structure, wherein the first groove does not extend to the depth of the plane containing the bonding interface, and forming the second groove through a bottom surface of the first groove to a depth beyond the plane containing the bonding interface.

20. The method of claim 17, wherein forming the groove in the semiconductor structure comprises forming the first groove in the surface of the semiconductor structure to a depth beyond the plane containing the bonding interface, and forming the second groove through a bottom surface of the first groove.
